(19) United States
(12) Patent Application Publication
(10) Pub. No.: US 2016/0240159 A1
(43) Pub. Date: Aug. 18, 2016

(54) SHIFT REGISTER AND DISPLAY DEVICE

(71) Applicant: SHARP KABUSHIKI KAISHA, Osaka-shi, Osaka (JP)

(72) Inventors: Hiroyuki OHKAWA, Osaka-shi (JP); Shige FURUTA, Osaka-shi (JP); Yuhichiroh MURAKAMI, Osaka-shi (JP)

(21) Appl. No.: 15/027,733

(22) PCT Filed: Oct. 8, 2013
(86) PCT No.: PCT/JP2014/072121

§ 371 Date: Apr. 7, 2016

(30) Foreign Application Priority Data
Oct. 8, 2013 (JP) 2013-211420

(51) Int. Cl. G09G 3/36; G11C 19/28

(52) U.S. Cl. CPC G09G 3/3677; G11C 19/28; G09G 2300/0814; G09G 2310/0286

(57) ABSTRACT

A shift register includes a plurality of unit circuits connected in cascade, each of the unit circuits including: a first output transistor having a current path connected between an output terminal and a clock terminal, the clock terminal being configured to be supplied with a first clock signal; a second output transistor having a current path connected between the output terminal and a predetermined potential node; a setting unit configured to set a signal level of the output terminal to a predetermined signal level in a case where a control signal is active; a first output controller configured to turn off the first output transistor in response to the control signal in the case where the control signal is active, supply a control electrode of the first output transistor with an input signal in response to one of a second clock signal in a case where the control signal is inactive; and a second output controller configured to turn off the second output transistor in the case where the control signal is active.

### TECHNICAL FIELD

The present invention relates to a shift register and a display device, particularly, a shift register used in a drive circuit of a display device.

Priority is claimed on Japanese Patent Application No. 2013-211420 filed Oct. 8, 2013, the content of which is incorporated herein by reference.

### BACKGROUND ART

In recent years, in an active matrix type display device, a so-called monolithic circuit technology is widely used in which a thin film transistor for a pixel adapted to inject electric charge to a pixel and a thin film transistor for a peripheral circuit constituting a peripheral circuit such as a drive circuit to drive a scanning line or a signal line connected to the thin film transistor for a pixel are formed on the same glass substrate.

In this type of display device, display elements two-dimensionally arrayed are selected per row by a scanning line drive circuit, and an image is displayed by writing a voltage according to display data in the selected display elements. A shift register that sequentially shifts output signals based on a clock signal is used as such a scanning line line drive circuit. In a display device that performs a dot-sequential drive, a similar shift register is provided inside a signal line drive circuit to drive a signal line.

In the case of using the shift registers as the scanning line drive circuit and the signal line drive circuit, an image may be disturbed by unstable operation of the shift register when a power circuit of a liquid crystal display device is turned on or off. In this case, disturbance of the image displayed on a screen can be reduced by performing all-on operation that allows all of output terminals of the shift register to output high-level output signals at the same time. The shift register capable of performing such all-on operation is disclosed in, for example, WO2012/029799 (Patent Document 1).

FIG. 22 is a diagram illustrating an exemplary configuration of a shift register according to the related art disclosed in WO2012/029799. The shift register illustrated in this drawing is formed by dependently connecting multi-stage shift register unit circuits SRU1, SRU2, SRU3, . . . , SRUn (n is a natural number equal to 2 or more). In each of the shift register unit circuits SRU1, SRU2, SRU3, . . . , SRUn, clock signals CK1, CK2, and all-on control signals AON, AONB (AONB is an inverted signal of the AON) are supplied. Furthermore, a start pulse signal ST is received in a set terminal SET of a first stage shift register unit circuit SRU1, and an output terminal OUT of a previous stage shift register unit circuit is connected to each of the set terminals SET of second and subsequent stage shift register unit circuits SRU2, SRU3, . . . , SRUn. Each of the output terminals OUT of the shift register unit circuits SRU1, SRU2, SRU3, . . . , SRUn is connected to each of scanning lines GL1, GL2, GL3, . . . , GLn. Each of the shift register unit circuits SRU1, SRU2, SRU3, . . . , SRUn has the same configuration, and when any one of the shift register unit circuits SRU1, SRU2, SRU3, . . . , SRUn is indicated, the shift register unit circuit will be referred to as a “shift register unit circuit SRU”.

FIG. 23 is a diagram illustrating an exemplary configuration of the shift register unit circuit SRU according to the related art illustrated in FIG. 22 described above. The shift register unit circuit SRU is formed of n channel Metal Oxide Semiconductor (MOS) field-effect transistors (hereinafter referred to as “NMOS transistors”) Q1 to Q9, a resistance R1, and capacitors CA, CB. Among them, the NMOS transistors Q5, Q6, Q7, resistance R1, and capacitor CB constitute an inactive output controller SRUA, the NMOS transistors Q1, Q4, Q8 constitute an active output controller SRUB, the NMOS transistors Q2, Q9 and the capacitor CA constitute an active output unit SRUC, and the NMOS transistor Q3 constitutes an inactive output unit SRUD. The active output controller SRUB sets an output signal to a high level by controlling the active output unit SRUC, and the inactive output controller SRUA sets an output signal to a low level by controlling the inactive output unit SRUD.

Among the multi-stage shift register unit circuits SRU1, SRU2, SRU3, . . . , SRUn, the clock signal CK1 and the clock signal CK2 are respectively received in a clock terminal CK and a clock terminal CKB in an odd-numbered stage shift register unit circuit SRU, and the clock signal CK2 and the clock signal CK1 are respectively received in a clock terminal CK and a clock terminal CKB in an even-numbered stage shift register unit circuit SRU, contrary to the odd-numbered shift register unit circuit. The clock signal CK1 and the clock signal CK2 are, for example, clock signals having phases deviated by 180 degrees from each other, and low-level sections of the respective signals are set such that both of the signals become the high level at the same time. Note that a phase difference between the clock signal CK1 and the clock signal CK2 is not limited to 180 degrees, and the clock signal CK1 and the clock signal CK2 may be any clock signals under the condition that both do not mutually have an overlapping period to become the high level.

Next, operation of the shift register according to the above-described related art will be described.

FIGS. 24A and 24B are time charts to describe exemplary operation of the shift register according to the related art. FIG. 24A is a time chart during normal operation, and FIG. 24B is a time chart during all-on operation. In FIGS. 24A and 24B, the high level and the low level of the start pulse signal ST and clock signals CK1, CK2 respectively correspond to power supply voltage VDD and ground voltage VSS supplied to the shift register. Furthermore, in FIGS. 24A and 24B, N11 and N21 represent nodes N1 and N2 of the first stage shift register unit circuit SRU1, N12 and N22 represent nodes N1 and N2 of the second stage shift register unit circuit SRU2, N1n and N2n represent nodes N1 and N2 of n^{th} stage shift register unit circuit SRUn, and OUT1, OUT2, OUTn represent output signals of the first, second, and n^{th} stage shift register unit circuits SRU.

First, the normal operation will be described. In the normal operation, the all-on control signal AON is set to the low level, and the all-on control signal AONB that is the inverted signal thereof is set to the high level. When the start pulse signal ST is received in the set terminal SET of the first stage shift register unit circuit SRU1 at time t0, the NMOS transistor Q1 is turned on in the active output controller SRUB and the node N11 is precharged to voltage (VDD−Vth) decreased from the power supply voltage VDD by threshold voltage Vth of the NMOS transistor Q1.

In this case, both the clock signal CK2 received in the clock terminal CKB and the start pulse signal ST received in the set terminal SET become the high level together in the inactive output controller SRUA. Therefore, all of the NMOS transistors Q5, Q6, Q7 are turned on. However, since the resistance R1 has high resistance, the voltage at the node N21 becomes the low level close to the ground voltage VSS. Consequently, a signal level at a gate of each of the NMOS transistors Q3, Q4 becomes the low level, and both of the NMOS transistors Q3, Q4 become an OFF-state.

After that, when each signal level of the clock signal CK2 received in the clock terminal CKB and the start pulse signal ST received in the set terminal SET becomes the low level of the ground voltage VSS, the NMOS transistors Q5, Q7 are turned off. Therefore, the node N21 becomes a floating state, but voltage at the node N21 is maintained by the capacitor CB. Furthermore, when the signal level of the start pulse signal ST received in the set terminal SET becomes the low level of the ground voltage VSS, the NMOS transistor Q1 is turned off. Therefore, the node N11 becomes a floating state, but voltage at the node N11 is maintained by the capacitor CA.

Subsequently, when the clock signal CK1 received in the clock terminal CK is changed to the high level at time t1, source voltage of the NMOS transistor Q2 is boosted. When the source voltage of the NMOS transistor Q2 is boosted, the voltage at the node N11 is boosted to voltage higher than the power supply voltage VDD due to a bootstrap effect by the capacitor CA. When gate voltage at the NMOS transistor Q2 becomes high voltage, the NMOS transistor Q2 transmits the high level of the clock signal CK1 received in the clock terminal CK to the output terminal OUT1 without voltage drop caused by threshold voltage Vth thereof. Consequently, the output signal OUT1 is made to become the high level and activated.

After that, when the clock signal CK2 received in the clock terminal CKB is changed to the high level at time t2, the voltage at the node N21 is boosted by the NMOS transistor Q5 being turned on. When the voltage at the node N21 is boosted, gate voltage is boosted at the NMOS transistor Q3 and the NMOS transistor Q4, and the NMOS transistor Q3 and NMOS transistor Q4 are turned on together. Then, discharge at the node N11 and pull-down at the output terminal OUT are simultaneously performed. Consequently, the output signal OUT1 is made to become the low level and inactivated. After that, every time the signal level of the clock signal CK2 received in the clock terminal CKB becomes periodically the high level, the NMOS transistor Q5 is turned on, thereby maintaining a signal level at the node N21 at the high level. As a result, after time t2, both of the NMOS transistors Q3, Q4 are maintained in the ON-state together, and the output signal OUT1 is maintained at the low level.

The same is performed in the subsequent stage shift register unit circuit SRU2, and the output signal from the output terminal OUT1 of the first stage shift register unit circuit SRU1 is received in the set terminal SET in the second stage shift register unit circuit SRU2 at time t1, thereby precharging the node N12. Then, at time t2, an output signal OUT2 is output from an output terminal OUT of the second stage shift register unit circuit SRU2. After that, when the clock signal CK1 is changed to the high level at time t3, discharge at the node N12 and pull-down at the output terminal OUT are simultaneously performed in the second stage shift register unit circuit SRU2. Then, the output signal OUT2 is made to become the low level and inactivated.

In the following, the same operation is repeated up to a final stage shift register unit circuit SRUn. As a result, the multiple shift register unit circuits SRU1, SRU2, SRU3, . . . , SRUn perform shift operation, and sequentially output high-level pulse signals to the scanning lines GL1, GL2, GL3, . . . , GLn.

According to this shift register, stable shift operation can be performed without generating through-current by using only two-phase clock signals CK1, CK2 and the output signal of the previous stage as the input signals.

Next, a description will be provided for all-on operation that allows all of the output terminals OUT of the multiple shift register unit circuits SRU1, SRU2, SRU3, . . . , SRUn constituting the shift register to simultaneously output high-level output signals.

In the case of starting the all-on operation, the all-on control signal AON is set to the high level, and the all-on control signal AONB that is the inverted signal thereof is set to the low level. Furthermore, in this example, all of the start pulse signal ST and the clock signals CK1, CK2 are set to the high level.

When the all-on control signal AON is set to the high level and the all-on control signal AONB is set to the low level, the NMOS transistor Q9 becomes the ON-state and the NMOS transistor Q8 becomes the OFF-state in the first stage shift register unit circuit SRU1. Furthermore, in this case, the NMOS transistor Q6 is turned off and the NMOS transistor Q7 is turned on. Therefore, the node N21 becomes the low-level (ground voltage VSS) and the NMOS transistor Q3 having the gate connected to the node N21 is turned off. Consequently, an element that drives the output terminal OUT to the low-level is eliminated. When the NMOS transistor Q9 becomes the ON-state in such a state, the high-level output signal OUT1 is output to the output terminal OUT.

In the second and subsequent stage shift register unit circuits SRU2, SRU3, . . . , SRUn, the high-level output signal is received in the set terminal SET from the output terminal OUT of the previous stage. Therefore, the same operation as the first stage is performed in the second and subsequent stage shift register unit circuits. Accordingly, all of the output signals output to the scanning lines GL1, GL2, GL3, . . . , GLn from the shift register unit circuits SRU1, SRU2, SRU3, . . . , SRUn become the high level, thereby performing the all-on operation.

Here, according to the technology disclosed in Patent Document 1, when the all-on control signal AON and the start pulse signal ST received in the set terminal SET become the high level during the all-on operation, the NMOS transistors Q5, Q7 are turned on together, but the all-on control signal AONB becomes the low level and the NMOS transistor Q6 is turned off. Therefore, through-current inside the inactive output controller SRUA is cut off.

Furthermore, when the all-on control signal AON becomes the high level and the all-on control signal AONB becomes the low level during the all-on operation, the thin film transistor Q8 is turned off together with the NMOS transistor Q6. Consequently, through-current inside the active output controller SRUB is cut off. Furthermore, when the NMOS transistor Q6 is turned off, the signal level at the node N2 is made to become the low level by the NMOS transistor Q7 based on a signal received in the set terminal SET. When the signal level at the node N2 is made to become the low level, the NMOS transistor Q3 having the gate connected to the node N2 is turned off. Therefore, through-current flowing in the NMOS transistors Q2, Q3 is also prevented.

### CITATION LIST

### Patent Document

[Patent Document 1]

PCT International Publication No. WO 2012/029799

### DISCLOSURE OF THE INVENTION

### Problems to be Solved by the Invention

The number of transistors in a shift register needs to be reduced in order to achieve slimmer bezel in a display device. However, according to the above-described related art, there may be a problem in that the number of transistors in the shift register is increased because NMOS transistors Q6, Q8 are provided because it is necessary to prevent through-current and the like during all-on operation. Furthermore, since an NMOS transistor Q1 and an NMOS transistor Q8 are connected in series, in the case of charging a node N1, charge voltage at the node N1 is decreased by threshold voltage Vth of the NMOS transistor Q1 and the NMOS transistor Q8, on-resistance, and so on. Therefore, there may be a disadvantage in that a signal level of an output signal output from an NMOS transistor Q2 having a gate connected to the node N1 is lowered.

An embodiment of the present invention is made in view of the above-described problem, and directed to providing a shift register in which the number of transistors can be reduced, and a display device including the shift register.

### Means for Solving the Problems

A shift register according to one aspect of the present invention is a shift register including a plurality of unit circuits dependently connected, each of the unit circuits including: a first output transistor having a current path connected between an output terminal and a clock terminal, the clock terminal being configured to be supplied with a first clock signal; a second output transistor having a current path connected between the output terminal and a predetermined potential node; a setting unit configured to set a signal level of the output terminal to a predetermined signal level in a case where a control signal is active, the control signal being adapted to set the levels of output signals of the plurality of unit circuits to the predetermined signal level; a first output controller configured to turn off the first output transistor in response to the control signal in the case where the control signal is active, turn on the first output transistor by supplying a control electrode of the first output transistor with an input signal in response to one of a second clock signal succeeding the first clock signal and a signal synchronized with the first clock signal in a case where the control signal is inactive; and a second output controller configured to turn off the second output transistor in the case where the control signal is active, and turn off the first output transistor and further turn on the second output transistor in response to a second clock signal succeeding the first clock signal in the case where the control signal is inactive.

### Effects of the Invention

According to an embodiment of the present invention, the number of transistors constituting the shift register can be reduced.

### BRIEF DESCRIPTION OF THE DRAWINGS

FIG. 1 is a schematic block diagram illustrating an exemplary configuration of a display device according to a first embodiment of the present invention.

FIG. 2 is a schematic block diagram illustrating an exemplary configuration of a shift register according to the first embodiment.

FIG. 3 is a circuit diagram illustrating an exemplary configuration of a shift register unit circuit according to the first embodiment.

FIG. 4A is a time chart illustrating a first exemplary operation of the shift register according to the first embodiment.

FIG. 4B is a time chart illustrating a second exemplary operation of the shift register according to the first embodiment.

FIG. 5 is a time chart to describe an exemplary operation in an on-sequence of a display device according to the first embodiment.

FIG. 6A is a time chart to describe a first exemplary operation in an off-sequence of the display device according to the first embodiment.

FIG. 6B is a time chart to describe a second exemplary operation in the off-sequence of the display device according to the first embodiment.

FIG. 7 is a time chart to describe an exemplary operation at the time of forced shutdown in the display device according to the first embodiment.

FIG. 8 is a circuit diagram illustrating an exemplary configuration of a shift register unit circuit according to a second embodiment.

FIG. 9A is a time chart illustrating a first exemplary operation of a shift register according to the second embodiment.

FIG. 9B is a time chart illustrating a second exemplary operation of the shift register according to the second embodiment.

FIG. 10 is a circuit diagram illustrating an exemplary configuration of a shift register unit circuit according to a third embodiment.

FIG. 11 is a circuit diagram illustrating an exemplary configuration of a shift register unit circuit according to a fourth embodiment.

FIG. 12 is a circuit diagram illustrating an exemplary configuration of a shift register unit circuit according to a fifth embodiment.

FIG. 13 is a circuit diagram illustrating an exemplary configuration of a shift register unit circuit according to a sixth embodiment.

FIG. 14A is a time chart illustrating a first exemplary operation of the shift register according to the sixth embodiment.

FIG. 14B is a time chart illustrating a second exemplary operation of the shift register according to the sixth embodiment.

FIG. 15 is a circuit diagram illustrating an exemplary configuration of a shift register unit circuit according to a seventh embodiment.

FIG. 16 is a schematic block diagram illustrating an exemplary configuration of a shift register according to an eighth embodiment.

FIG. 17 is a circuit diagram illustrating an exemplary configuration of a shift register unit circuit according to the eighth embodiment.

FIG. 18A is a circuit diagram illustrating a first detailed example of a shift register unit circuit according to the eighth embodiment.

FIG. 18B is a circuit diagram illustrating a second detailed example of the shift register unit circuit according to the eighth embodiment.

FIG. 18C is a circuit diagram illustrating a third detailed example of the shift register unit circuit according to the eighth embodiment.

FIG. 19A is a time chart illustrating a first exemplary operation of a shift register according to the eighth embodiment.

FIG. 19B is a time chart illustrating a second exemplary operation of the shift register according to the eighth embodiment.

FIG. 19C is a time chart illustrating a third exemplary operation of the shift register according to the eighth embodiment.

FIG. 20 is a circuit diagram illustrating an exemplary configuration of a shift register unit circuit according to a ninth embodiment.

FIG. 21A is a time chart illustrating a first exemplary operation of the shift register according to the ninth embodiment.

FIG. 21B is a time chart illustrating a first exemplary operation of the shift register according to the ninth embodiment.

FIG. 22 is a block diagram illustrating an exemplary configuration of a shift register according to the related art.

FIG. 23 is a circuit diagram illustrating an exemplary configuration of the shift register unit circuit according to the related art.

FIG. 24A is a time chart illustrating a first exemplary operation of the shift register according to the related art.

FIG. 24B is a time chart illustrating a second exemplary operation of the shift register according to the related art.

### MODE FOR CARRYING OUT THE INVENTION

### First Embodiment

### Description of Configuration

A first embodiment of the present invention will be described.

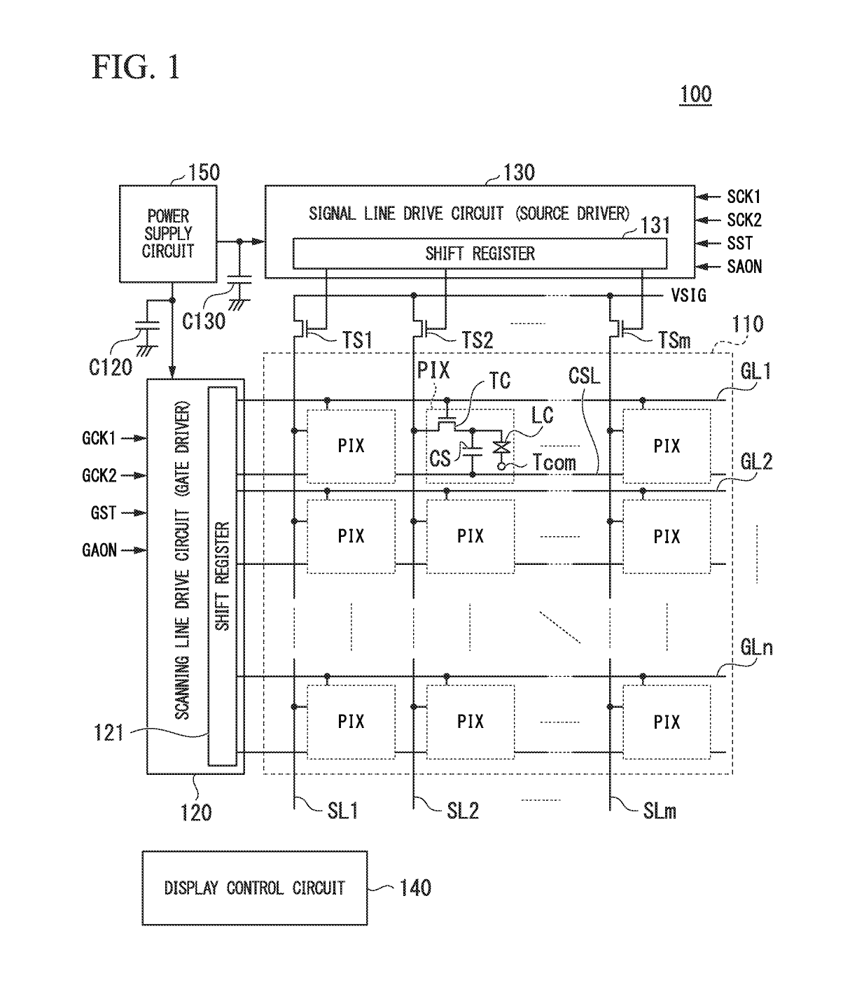

FIG. 1 is a schematic block diagram illustrating an exemplary configuration of a display device 100 according to the first embodiment of the present invention. The display device 100 is, for example, an active matrix liquid crystal display device and includes a display unit 110, a scanning line drive circuit (gate driver) 120, a signal line drive circuit (source driver) 130, a display control circuit 140, a power supply circuit 150, thin film transistors for signal line selection (analog switches) TS1, TS2, . . . , TSm, and other circuits.

The display unit 110 includes a plurality of signal lines SL1, SL2, . . . , SLm (m: natural number) arranged in a manner extending in a vertical line direction, a plurality of scanning lines GL, GL2, . . . , GLn (n: natural number) arranged in a manner extending in a horizontal line direction, and a plurality of pixel portions PIX.

The plurality of pixel portions PIX is arranged in a matrix so as to be located at intersections between the signal lines SL1, SL2, . . . , SLm and the scanning lines GL1, GL2, . . . , GLn, and forms a display area of the display device 100. Furthermore, each of the plurality of pixel portions PIX includes a liquid crystal (liquid crystal material) LC disposed between two substrates, a thin film transistor for a pixel TC disposed on one of the substrates, a pixel capacitance portion (auxiliary capacitance) CS formed of the liquid crystal LC, and a counter electrode (transparent electrode) Tcom disposed on the other substrate.

The thin film transistor for a pixel TC has a gate connected to a scanning line GLp (p is any integer satisfying the following condition p: 1≦p≦n) passing through the mentioned intersections, a source connected to a signal line SLq (q is any integer satisfying the following condition q: 1≦q≦m), and a drain connected to a first terminal of the pixel capacitance portion CS. The pixel capacitance portion CS maintains voltage according to each pixel value (gradation value) based on a data signal to display a video (image) on the display device 100. A second terminal of the pixel capacitance portion CS is connected to an auxiliary capacitance electrode line CSL.

Meanwhile, in the present embodiment, the auxiliary capacitance electrode line CSL is provided assuming that a vertical alignment (VA) system is adopted. However, the present invention is not limited to this example and can be applicable to any system such as an in-plane switching (IPS) system. For example, a second electrode of the pixel capacitance portion CS may be connected to the counter electrode Tcom.

In the present embodiment, the thin film transistor for a pixel TC is an n channel field-effect transistor. Note that the thin film transistor for a pixel TC is not limited to the n channel thin film transistor, and any kind of transistor can be used.

The scanning line drive circuit 120 is formed by including a shift register 121, and sequentially supplies scanning signals (gate signals G1, G2, . . . , Gn described later) to the scanning lines GL1, GL2, . . . , GLn by this shift register 121. In response to the scanning signals supplied from the shift register 121, the pixel portions PIX are driven per horizontal line. When the shift register 121 sequentially shifts a gate start pulse signal GST in synchronization with gate clock signals GCK1, GCK2, the scanning line drive circuit 120 outputs the scanning signals to the respective scanning lines GL1, GL2, . . . , GLn at predetermined time intervals. Furthermore, the scanning line drive circuit 120 has a function to set all of the scanning signals supplied to the scanning lines GL1, GL2, . . . , GLn to a high level (predetermined signal level) based on a gate all-on control signal GAON during all-on operation that allows all of output terminals of the shift register to simultaneously output high-level output signals. The scanning line drive circuit 120 is formed of a thin film transistor for a peripheral circuit formed on a glass substrate in the same manner as the above-described thin film transistor for a pixel TC. This thin film transistor for a peripheral circuit is an n channel field-effect transistor the same as the thin film transistor for a pixel TC.

The signal line drive circuit 130 is formed by including a shift register 131. The signal line drive circuit 130 sequentially selects thin film transistors for signal line selection TS1, TS2, . . . , TSm by sequentially shifting a source start pulse signal SST in synchronization with source clock signals SCK1, SCK2, and outputs data signals VSIG to the signal lines SL1, SL2, . . . , SLm via the thin film transistors for signal line selection TS1, TS2, . . . , TSm. The data signal VSIG supplies each of the pixel portions PIX with the voltage according to a pixel value (gradation value). In this case, the signal line drive circuit 130 supplies the data signal VSIG for one horizontal line to each of the pixel portions PIX via each of the signal lines SL1, SL2, . . . , SLm selected by each of the thin film transistors for signal line selection TS1, TS2, . . . , TSm.

The signal line drive circuit 130 has a function to select all of the signal lines SL1, SL2, . . . , SLm by the thin film transistors for signal line selection TS1, TS2, . . . , TSm based on a source all-on control signal SAON to set all of the signal lines to a high level (predetermined signal level) during all-on operation. Furthermore, the signal line drive circuit 130 is formed of a thin film transistor for a peripheral circuit formed on the glass substrate the same as the thin film transistor for a pixel TC in the same manner as the scanning line drive circuit 120.

Meanwhile, in the present embodiment, the scanning line drive circuit 120 and the signal line drive circuit 130 are formed on the glass substrate the same as the thin film transistor for a pixel TC, but not limited thereto. Only the scanning line drive circuit 120 may be formed on the glass substrate the same as the thin film transistor for a pixel TC, and a data signal may be supplied from an external integrated circuit (IC) having the function of the signal line drive circuit 130. Furthermore, only the signal line drive circuit 130 may be formed on the glass substrate the same as the thin film transistor for a pixel TC, and the scanning line drive circuit 120 may be provided outside.

The display control circuit 140 is adapted to generate various kinds of control signals required to display an image on the display unit 110 and supply such control signals to the scanning line drive circuit 120 and the signal line drive circuit 130. In the present embodiment, the display control circuit 140 generates a control signal to display an image on the display unit 110 during an image display period, and supplies the control signal to the scanning line drive circuit 120 and the signal line drive circuit 130. For example, the display control circuit 140 generates the above-described gate clock signals GCK1, GCK2, source clock signals SCK1, SCK2, gate start pulse signal GST, source start pulse signal SST, gate all-on control signal GAON, source all-on control signal SAON, data signal VSIG, and so on.

The power supply circuit 150 is adapted to supply operation power supply voltage (VDD, VH, VL, etc.) for the scanning line drive circuit 120 and the signal line drive circuit 130. Capacitance C120 is formed on power supply wiring between the power supply circuit 150 and the scanning line drive circuit 120, and capacitance C130 is formed on power supply wiring between the power supply circuit 150 and the signal line drive circuit 130.

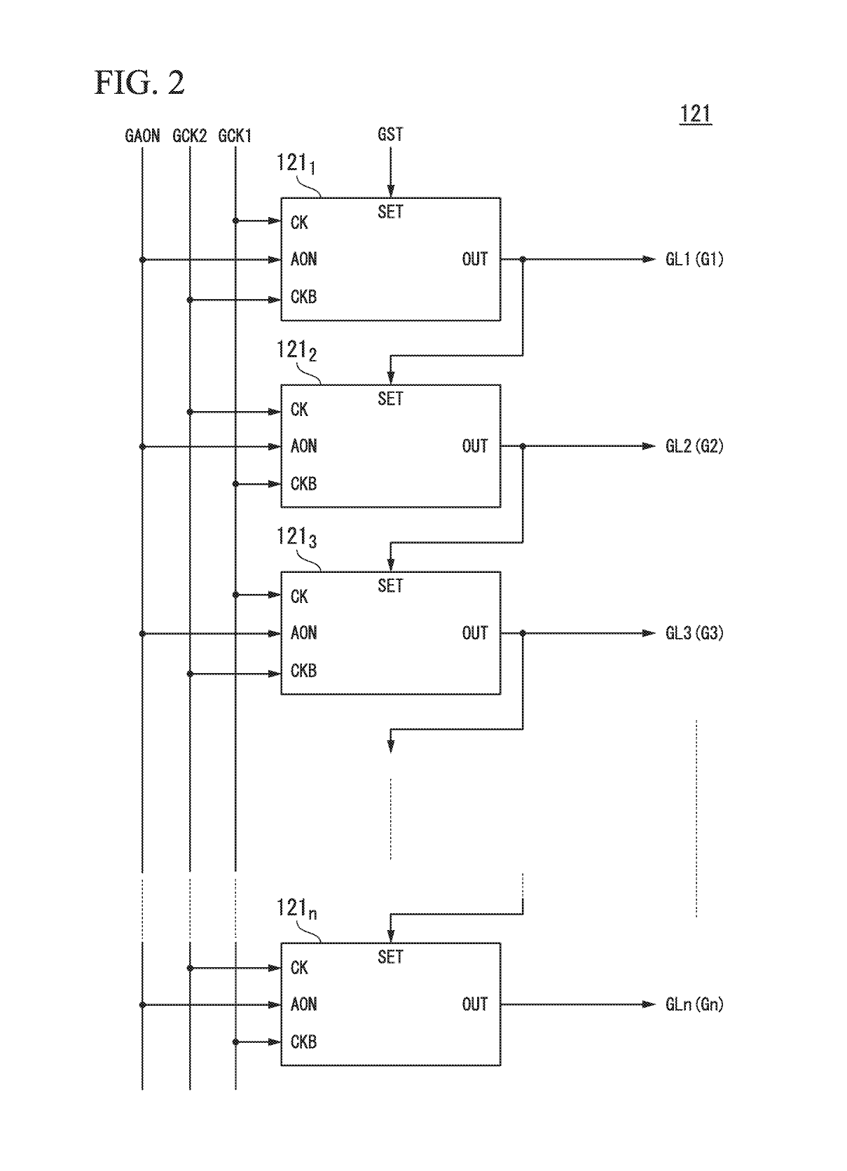

Next, a configuration of the shift register 121 according to the first embodiment will be described with reference to FIG. 2. FIG. 2 is a schematic block diagram illustrating an exemplary configuration of the shift register 121 according to the first embodiment. As illustrated in FIG. 2, the shift register 121 includes a plurality of shift register unit circuits 121₁, 121₂, 121₃, . . . , 121ₙ corresponding to a plurality of scanning lines GL1, GL2, GL3, . . . , GLn. The plurality of shift register unit circuits 121₁, 121₂, 121₃, . . . , 121ₙ, is connected in cascade.

Each of the plurality of shift register unit circuits 121₁, 121₂, 121₃, . . . , 121ₙ has the same configuration, and when each of the shift register unit circuits 121₁, 121₂, 121₃, . . . , 121, is indicated hereinafter, the shift register unit circuit will be collectively referred to as a “shift register unit circuit 1211” for convenience. The shift register unit circuit 1211 includes clock terminals CK, CKB, a set terminal SET, an output terminal OUT, and an all-on control terminal AON.

In odd-numbered stage shift register unit circuits among the plurality of shift register unit circuits 121₁, 121₂, 121₃, . . . , 121ₙ, the gate clock signal GCK1 is received in the clock terminal CK and the gate clock signal GCK2 is received in the clock terminals CKB. In contrast, in an even-numbered stage shift register unit circuit, the gate clock signal GCK2 is received in the clock terminal CK and the gate clock signal GCK1 is received in the clock terminal CKB. The gate all-on control signal GAON is received in the all-on control terminal AON in each of the plurality of shift register unit circuits 121₁, 121₂, 121₃, . . . , 121ₙ. Among the plurality of shift register unit circuits 121₁, 121₂, 121₃, . . . , 121ₙ, the gate start pulse signal GST is received in a set terminal SET in a first stage shift register unit circuit 121₁, and an output signal of a previous stage shift register unit circuit is received in the set terminal SET in each of second and subsequent stage shift register unit circuits.

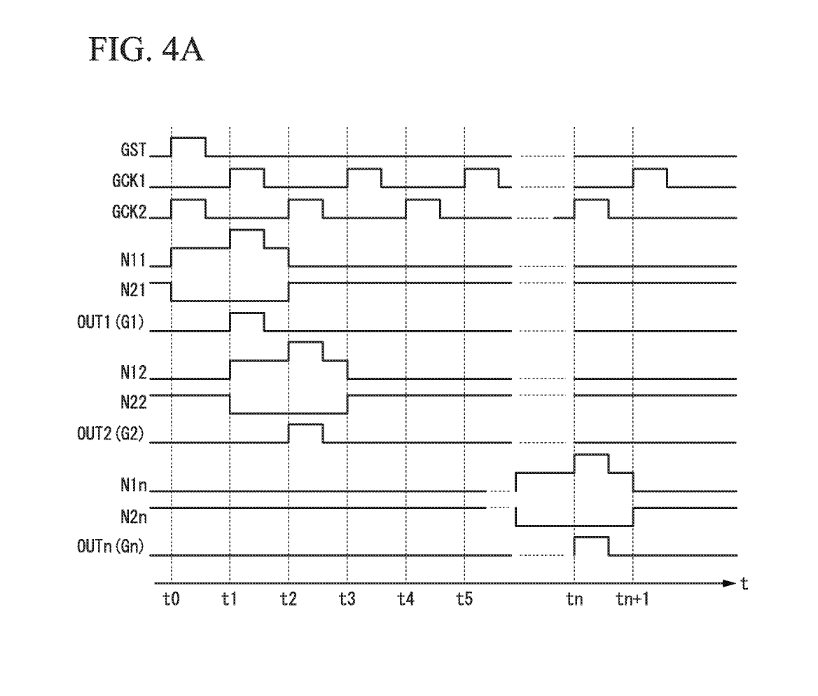

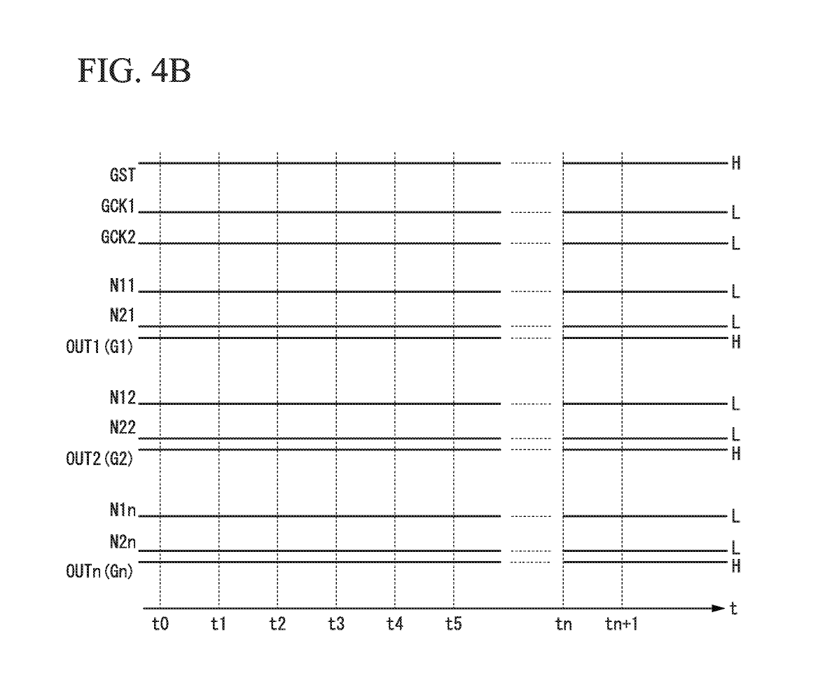

When the shift register 121 formed of multi-stage shift register unit circuits 121₁, 121₂, 121₃, . . . , 121ₙ receives the gate start pulse signal GST from the display control circuit 140, the shift register 121 performs shift operation based on the gate clock signals GCK1, GCK2, and sequentially outputs the gate signals G1, G2, G3, . . . , Gn to the scanning lines GL1, GL2, GL3, . . . , GLn. In the present embodiment, a phase of the gate clock signal GCK1 and a phase of the gate clock signal GCK2 differ from each other by 180 degrees as illustrated in FIGS. 4A and 4B described later. Furthermore, a low level section is set such that the gate clock signal GCK1 and the gate clock signal GCK2 do not become the high level at the same time. However, the phase difference between the gate clock signal GCK1 and the gate clock signal GCK2 is not limited to 180 degrees, and the clock signal CK1 and the clock signal CK2 may be any clock signals under the condition that both do not mutually have an overlapping period to become the high level. Furthermore, each of the signal levels in the mentioned non-overlapping period may be any signal level in accordance with each of logics (positive logic/negative logic) of the gate clock signal GCK1 and the gate clock signal GCK2. The same is applied to the source clock signals SCK1, SCK2.

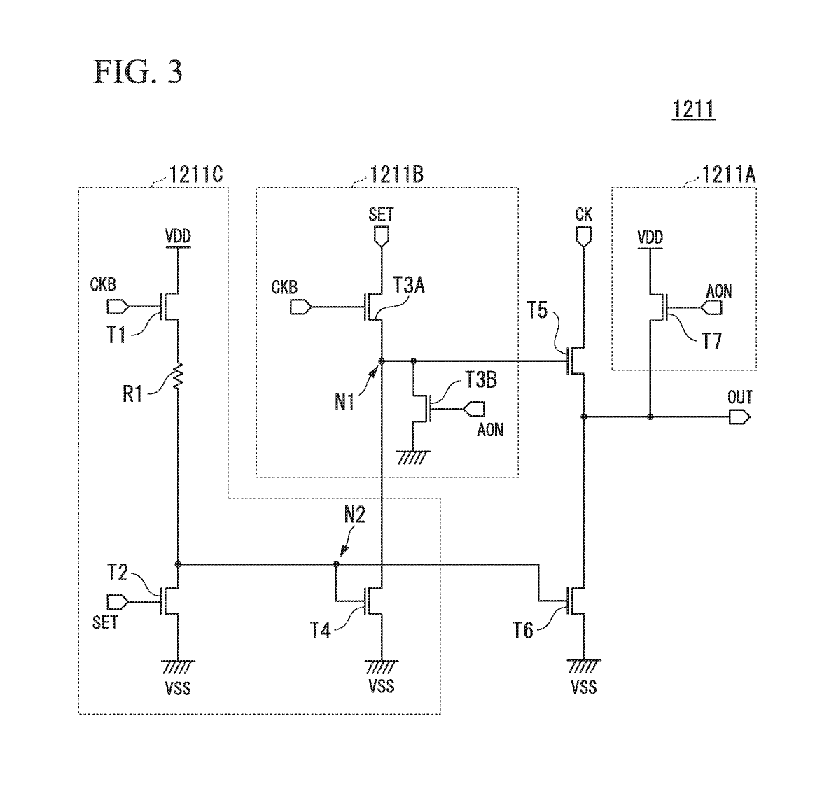

Next, a configuration of the shift register unit circuit 1211 according to the present embodiment will be described with reference to FIG. 3. FIG. 3 is a circuit diagram illustrating an exemplary configuration of the shift register unit circuit 1211 according to the first embodiment.

The shift register unit circuit 1211 includes thin film transistors T1, T2, T3A, T3B, T4, T5, T6, T7 that are n channel field-effect transistors, and a resistance R1. The thin film transistor T1 has a drain applied with the power supply voltage VDD and a gate connected to the clock terminal CKB. The gate clock signal GCK2 is received in the clock terminal CKB. When the gate clock signal GCK2 received in the clock terminal CKB becomes the high level, the thin film transistor T1 outputs, from the source, a decreased voltage by threshold voltage Vth of the thin film transistor T1, based on gate voltage thereof.

The resistance R1 has one end connected to a source of the thin film transistor T1 and the other end connected to a drain of the thin film transistor T2. A resistance value of the resistance R1 is set to a high value such that drain voltage of the thin film transistor T2 becomes a sufficiently low level to turn off the thin film transistors T4, T6 in a state that both of the thin film transistor T1 and the thin film transistor T2 are turned on.

Meanwhile, an arrangement position of the resistance R1 and an arrangement position of the thin film transistor T1 may be switched.

More specifically, the resistance R1 may have one end supplied with the power supply voltage VDD, and the resistance R1 may have the other end connected to the drain of the thin film transistor T1, and the drain of the thin film transistor T2 may be connected to the source of the thin film transistor T1.

The thin film transistor T2 has a source connected to a ground node (predetermined potential node), and a gate connected to the set terminal SET. The gate start pulse signal GST or the output signal from the previous stage shift register unit circuit is received in the set terminal SET. More specifically, the gate start pulse signal GST is received in the set terminal SET of the first stage shift register unit circuit 121₁, and the output signal of the previous stage shift register unit circuit is received in the set terminal SET in each of the second and subsequent stage shift register unit circuits 121₂, 121₃, . . . , 121ₙ. When the signal received in the set terminal SET becomes the high level, the thin film transistor T2 is turned on, and outputs a low level corresponding to the ground voltage VSS from the drain thereof.

The thin film transistor T3A has a drain connected to the set terminal SET supplied with an input signal, a gate connected to the clock terminal CKB supplied with the gate clock signal GCK2, and a source connected to a drain of the thin film transistor T4. In the case where the gate clock signal GCK2 received in the clock terminal CKB is the high level and the input signal received in the set terminal SET is the high level, the thin film transistor T3A outputs, from the source, a decreased voltage by the threshold voltage Vth of the thin film transistor T3A, based on gate voltage thereof. A gate of the thin film transistor T5 is connected to a connection point between the source of the thin film transistor T3A and the drain of the thin film transistor T4. Furthermore, a drain of the thin film transistor T3B is connected to a connection point between the source of the thin film transistor T3A and the drain of the thin film transistor T4, a source of the thin film transistor T3B is connected to a ground node (VSS), and a gate of the thin film transistor T3B is connected to the all-on control terminal AON supplied with the gate all-on control signal GAON.

The thin film transistor T4 has the drain connected to the source of the thin film transistor T3A, a gate connected to a connection point between the drain of the thin film transistor T2 and the resistance R1, and a source connected to the ground node. When a signal level at the connection point between the thin film transistor T2 and the resistance R1 becomes the high level, the thin film transistor T4 is turned on and outputs the low level corresponding to the ground voltage VSS from the drain thereof

The thin film transistor T5 (first output transistor) has a drain connected to the clock terminal CK, the gate connected to the connection point between the source of thin film transistor T3A and the drain of the thin film transistor T4, and a source connected to the output terminal OUT. The gate clock signal GCK1 is received in the clock terminal CK. When a signal level at the connection point between the source of the thin film transistor T3A and the drain of the thin film transistor T4 becomes the high level, the thin film transistor T5 transmits, to the output terminal OUT, the signal level of the gate clock signal GCK1 received in the clock terminal CK. At this point, for example, the high level of the gate clock signal GCK1 is supplied to the output terminal OUT via the thin film transistor T5 due to a bootstrap effect based on parasitic capacitance between the gate and the source of the thin film transistor T5 without voltage drop caused by the threshold voltage Vth of the thin film transistor T5.

The thin film transistor T6 (second output transistor) has a drain connected to the output terminal OUT, a gate connected to the connection point between the drain of the thin film transistor T2 and the resistance R1, and a source connected to the ground node. When a signal level at the connection point between the drain of the thin film transistor T2 and the resistance R1 becomes the high level, the thin film transistor T6 is turned on and outputs, to the output terminal OUT, the low level corresponding to the ground voltage VSS from the drain thereof.

The thin film transistor T7 has a drain supplied with the power supply voltage VDD, a gate connected to the all-on control terminal AON, and a source connected to the output terminal OUT. The gate all-on control signal GAON is received in the all-on control terminal AON. When the gate all-on control signal GAON received in the all-on control terminal AON becomes the high level, the thin film transistor T7 outputs, from the source, a decreased voltage by threshold voltage Vth of the thin film transistor T7 to the output terminal OUT, based on gate voltage thereof (high level of to the gate all-on control signal GAON).

Note that the thin film transistor T7 may also be provided in a form of a so-called diode connection.

More specifically, the thin film transistor T7 may have the gate connected to the drain, a source connected to the output terminal OUT, and the gate all-on control signal AON may be received in a connection point between the gate and the drain of the thin film transistor T7.

In the present embodiment, a node N1 is formed at the above-described connection point between the source of thin film transistor T3A and the drain of the thin film transistor T4, and a node N2 is formed at the connection point between the resistance R1 and the drain of the thin film transistor T2. Furthermore, in the present embodiment, the thin film transistor T5 forms the first output transistor having a current path connected between the clock terminal CK supplied with the clock signal CK1 and the output terminal OUT. Furthermore, the thin film transistor T6 forms the second output transistor having a current path connected between the output terminal OUT and the ground node (predetermined potential node). Moreover, the thin film transistor T7 forms a setting unit 1211A. When the gate all-on control signal GAON received in the all-on control terminal AON is active, the setting unit 1211A sets a signal level of the output terminal OUT to the high level (predetermined signal level). The gate all-on control signal GAON is adapted to set the levels of output signals of the plurality of shift register unit circuits 121₁, 121₂, 121₃, . . . , 121ₙ to the high level (predetermined signal level).

Additionally, in the present embodiment, the thin film transistors T3A, T3B form a first output controller 1211B. When the gate all-on control signal GAON is active, the first output controller 1211B turns off the thin film transistor T5 in response to the gate all-on control signal GAON. When the gate all-on control signal GAON is inactive, the first output controller 1211B turns on the thin film output transistor T5 by supplying an input signal of the set terminal SET to a control electrode of the thin film transistor T5 in response to the gate clock signal GCK2 succeeding the gate clock signal GCK1 or a signal synchronized with the gate clock signal GCK1. In the example of FIG. 3, when the gate all-on control signal GAON is inactive, the first output controller 1211B is adapted to supply the input signal of the set terminal SET to the control electrode of the thin film transistor T5 in response to the gate clock signal GCK2 received in the clock terminal CKB. However, when the gate all-on control signal GAON is inactive, the first output controller 1211B may also supply the input signal to the control electrode of the thin film transistor T5 in response to a signal synchronized with any one of the gate clock signal GCK2 and the gate clock signal GCK1.

Among the thin film transistors T3A, T3B included in the above-described first output controller 1211B, the thin film transistor T3A functions as the setting unit to set the signal level at the node N1 when the gate all-on control signal GAON is inactive. Furthermore, when the gate all-on control signal GAON is active, the thin film transistor T3B functions as a discharge circuit to discharge the node N1.

Furthermore, the thin film transistors T1, T2, T4 and the resistance R1 form a second output controller 1211C that turns off the thin film transistor T6 in the case where the gate all-on control signal GAON received in the all-on control terminal AON is active, and that turns off the thin film transistor T5 and further turns on the thin film transistor T6 in response to the gate clock signal GCK2 succeeding the gate clock signal GCK1 or the signal synchronized with the gate clock signal GCK1 in the case where the gate all-on control signal GAON is inactive. Meanwhile, in the present embodiment, the display control circuit 140 generates the gate clock signal GCK1 and the gate clock signal GCK2, and supplies the gate clock signals to the scanning line drive circuit 120.

However, the gate clock signal GCK1 and the gate clock signal GCK2 may be derivatively generated inside the scanning line drive circuit 120 from one clock signal supplied to the scanning line drive circuit 120. The above-described “signal synchronized with the gate clock signal GCK1” is a signal corresponding to the gate clock signal GCK2 in the case where the gate clock signal GCK2 is derivatively generated together with the gate clock signal GCK1 from one clock signal inside the scanning line drive circuit 120. In other words, a method of generating the gate clock signal GCK1 and the gate clock signal GCK2 is arbitrary, i.e., the gate clock signals may be generated either outside or inside the scanning line drive circuit 120.

The shift register unit circuit 1211 thus configured apparently fetches the signal received in the set terminal SET at a timing synchronized with the gate clock signal GCK2 received in the clock terminal CKB, and transfers the fetched signal to the output terminal OUT at a timing synchronized with the gate clock signal GCK1 received in the clock terminal CK. Consequently, the shift register unit circuit 1211 functions as a so-called master-slave flip-flop.

Next, the signal line drive circuit 130 will be described.

The shift register 131 included in the signal line drive circuit 130 basically has the same configuration as the shift register 121 included in the scanning line drive circuit 120, but differs from the shift register 121 of the scanning line drive circuit 120 in including m-stage shift register unit circuits corresponding to m signal lines SL1, SL2, . . . , SLm. The shift register unit circuit constituting the shift register 131 has the same configuration as the shift register unit circuit 1211 illustrated in FIG. 3.

However, in the configuration of the shift register unit circuit 1211 illustrated in FIG. 3, the source clock signal SCK1 is received in the clock terminal CK and the source clock signal SCK2 is received in the clock terminal CKB in each of the odd-numbered stage shift register unit circuits constituting the shift register 131. In contrast, the source clock signal SCK2 is received in the clock terminal CK and the source clock signal SCK1 is received in the clock terminal CKB in each of the even-numbered stage shift register unit circuits.

Furthermore, the source all-on control signal SAON is received in the all-on control terminal AON of each of the m-stage shift register unit circuits constituting the signal line drive circuit 130. Furthermore, among the m-stage shift register unit circuits constituting the signal line drive circuit 130, the source start pulse signal SST is received in the set terminal SET of the first stage shift register unit circuit, and the output signal from the previous stage shift register unit circuit is received in each of the set terminals SET of the second and subsequent stage shift register unit circuits.

Upon receipt of the source start pulse signal SST from the display control circuit 140, the m-stage shift register unit circuits constituting the shift register 131 perform shift operation based on the source clock signals SCK1, SCK2, and sequentially output selection signals to respective gates of the thin film transistors for signal line selection TS1, TS2, . . . , TSm. A phase of the source clock signal SCK1 and a phase of the source clock signal SCK2 differ from each other by 180 degrees in the same manner as the above-described gate clock signals GCK1, GCK2, and further a low level section in each of the source clock signals is set such that the source clock signal SCK1 and the source clock signal SCK2 do not become the high level at the same time.

Meanwhile, in the present embodiment, each of the shift register unit circuits 1211 constituting the scanning line drive circuit 120 and the signal line drive circuit 130 outputs the ground voltage VSS corresponding to the ground node as the low level of the output signal, and outputs the positive power supply voltage VDD as the high level of the output signal. However, not limited to this example, the shift register unit circuit 1211 may output negative voltage VL (for example, −5 V) as the low level and output positive voltage VH (for example, +10 V) as the high level. In this case, the ground voltage VSS (predetermined potential) illustrated in the respective drawings represents negative voltage.

### (Description of Operation)

Next, operation of the image display device 100 according to the present embodiment will be described.

Operational characteristics of the display device 100 according to the present embodiment are operation of the shift register 121 constituting the scanning line drive circuit 120 and operation of the shift register 131 constituting the signal line drive circuit 130. Therefore, operation of the shift register 121 constituting the scanning line drive circuit 120 will be described below in detail. The operation of the shift register 131 constituting the signal line drive circuit 130 is basically the same as that of the shift register 121, and a description for operation thereof will be omitted.

FIGS. 4A and 4B are time charts illustrating exemplary operation of the shift register 121 according to the first embodiment. FIG. 4A is a time chart during normal operation, and FIG. 4B is a time chart during all-on operation. In FIGS. 4A and 4B, the high level and the low level of the gate start pulse signal GST and the gate clock signals GCK1, GCK2 are respectively the signal levels corresponding to the operation power supply voltage VDD supplied to the shift register and the ground voltage VSS.

Furthermore, in the normal operation, the gate all-on control signal GAON is set to the low level. Furthermore, in FIGS. 4A and 4B, N11 and N21 represent the nodes N1 and N2 of the first stage shift register unit circuit 121₁, N12 and N22 represent the nodes N1 and N2 of the second stage shift register unit circuit 121₂, Nn and N2n represent the1 nodes N1 and N2 of an n^{th} stage shift register unit circuit 121ₙ, and OUT1, OUT2, OUTn represent output signals of the first, second, and n^{th} stage shift register unit circuits.

Note that “H” in the drawings represents the high level and “L” represents the low level.

### <Normal Operation>

First, normal operation of the shift register 121 will be described with reference to FIG. 4A.

Briefly speaking, in the normal operation of the shift register 121, the node N1 is precharged by the thin film transistor T3A based on the input signal in the set terminal SET and the gate clock signal GCK2 in the clock terminal CKB.

More specifically, in the normal operation, the gate all-on control signal GAON is set to the low level.

Consequently, the thin film transistors T7, T3B are maintained in the OFF-state. In this case, as illustrated in FIG. 4A, when the gate start pulse signal GST received in the set terminal SET of the first stage shift register unit circuit 1211 is changed to the high level and the gate clock signal GCK2 received in the clock terminal CKB is changed to the high level at time t0, the thin film transistor T3A is turned on. Furthermore, at time t0, the gate clock signal GCK2 received in the clock terminal CKB is changed to the high level and the gate start pulse signal GST received in the set terminal SET is also changed to the high level. Therefore, the thin film transistor T1 and the thin film transistor T2 are turned on together. At this point, current supplied from the thin film transistor T1 is suppressed by the resistance R1. Therefore, a signal level at the node N21 is made to become the low level close to the ground voltage VSS by the thin film transistor T2. When the node N21 is made to become the low level, the thin film transistor T4 and the thin film transistor T6 are turned off together. As a result, the node N11 is charged by the thin film transistor T3A to voltage (VDD−Vth) decreased by the threshold voltage Vth from the power supply voltage VDD (high level of the gate clock signal GCK2 received in the clock terminal CKB).

After that, when the gate start pulse signal GST received in the set terminal SET and the gate clock signal GCK2 received in the clock terminal CKB are changed to the low level, the thin film transistor T1 and the thin film transistor T2 are turned off together. Consequently, the node N21 becomes a floating state, and the signal level at the node N21 is maintained at the low level.

Furthermore, when the gate start pulse signal GST received in the set terminal SET and the gate clock signal GCK2 received in the clock terminal CKB become the low level, the thin film transistor T3A is turned off Therefore, the node N11 also becomes the floating state, thereby maintaining the voltage (VDD−Vth) charged to the node N11.

Next, when the gate clock signal GCK1 received in the clock terminal CK is changed to the high level at time t1, the high level of the gate clock signal GCK1 is transmitted to the output terminal OUT via the thin film transistor T5 having the drain connected to the clock terminal CK, and the signal level of the output signal OUT1 starts to be raised. When the signal level of the output signal OUT1 is raised, the signal level at the node N11 is pushed up due to the bootstrap effect of a capacitance component provided between the gate and source of the thin film transistor T5. Therefore, gate voltage at the thin film transistor T5 is increased higher than source voltage of the thin film transistor T5, and the thin film transistor T5 is turned on. Consequently, the high level (signal level corresponding to the power supply voltage VDD) of the gate clock signal GCK1 received in the clock terminal CK is transmitted to the output terminal OUT without voltage drop caused by the threshold voltage Vth of the thin film transistor T5. As a result, the shift register unit circuit 121₁ outputs, as the output signal OUT1, the gate signal G1 having the high level corresponding to the power supply voltage VDD.

Subsequently, when the gate clock signal GCK2 received in the clock terminal CKB is changed to the high level at time t2, the thin film transistor T1 is turned on, and the node N21 is charged through the thin film transistor T1 and the resistance R1. Then, the voltage at the node 21 is boosted. Consequently, the thin film transistors T4, T6 each having the gate connected to the node N21 are turned on together, and the thin film transistors T4, T6 pull down the node N11 and the output terminal OUT respectively. As a result, the thin film transistor T5 having the gate connected to the node N11 is turned off, and further the output signal OUT1 is changed to the low level.

After that, the gate start pulse signal GST received in the set terminal SET is maintained at the low level. Therefore, the thin film transistor T2 is maintained in the OFF-state. Furthermore, the thin film transistor T1 is periodically turned on in response to the high level of the gate clock signal GCK2 periodically received in the clock terminal CKB, thereby maintaining the node N21 in a state charged to the high level. Consequently, the thin film transistors T4, T6 each having the gate connected to the node N21 are maintained in the ON-state. Furthermore, in this case, every time a pulse of the high level of the gate clock signal GCK2 arrives, the thin film transistor T3A periodically becomes the ON-state, and the gate start pulse signal GST having the low level is transmitted to the node N11 via the thin film transistor T3A. Consequently, the node N11 is periodically discharged via the thin film transistor T3A. Furthermore, in this case, the node N11 is pulled down by the thin film transistor T4 that is in the ON-state. Therefore, the signal level at the node N11 is maintained at the low level corresponding to the ground potential VSS. As a result, the thin film transistor T5 having the gate connected to the node N11 is maintained in the OFF-state, and the output signal OUT1 is maintained at the low level by the thin film transistor T6 maintained in the ON-state.

Operation of the second stage shift register unit circuit 121₂ is performed delayed by ½ clock from operation of the first stage shift register unit circuit 121₁ upon receipt of the output signal OUT1 of the first stage shift register unit circuit 121₁. The operation of the second stage shift register unit circuit 121₂ is the same as that of the first stage shift register unit circuit 121₁, and the shift register unit circuit 121₂ changes the output signal OUT2 to the high level at time t2 that is ½ clock delayed from the output signal OUT1 of the first stage shift register unit circuit 121₁. After that, in the same manner, the third and subsequent stage shift register unit circuits 121₃, . . . , 121ₙ sequentially output the output signals OUT3, . . . , OUTn respectively delayed by ½ clock from the output signal of the previous stage shift register unit circuit.

### <All-On Operation>

Next, all-on operation in the shift register 121 will be described with reference to FIG. 4B.

Briefly, in the all-on operation of the shift register 121, the thin film transistor T3A becomes the OFF-state and further the node N1 is pulled down by the thin film transistor T3B.

More specifically, in the all-on operation, the gate all-on control signal GAON is set to the high level. Furthermore, as illustrated in FIG. 4B, the gate start pulse signal GST is set to the high level and the gate clock signals GCK1, GCK2 are set to the low level. In this case, in the first stage shift register unit circuit 121₁, the thin film transistor T1 having the gate connected to the clock terminal CKB in which the gate clock signal GCK2 set to the low level is received is turned off. Furthermore, the thin film transistor T2 having the gate connected to the set terminal SET in which the gate start pulse signal GST set to the high level is received is turned on. Consequently, the node N21 is pulled down by the thin film transistor T2, and the signal level at the node N21 becomes the low level. As a result, the thin film transistors T4, T6 each having the gate connected to the node N21 are turned off together.

Furthermore, the thin film transistor T3A having the gate connected to the clock terminal CKB in which the gate clock signal GCK2 set to the low level is received is turned off. On the other hand, the thin film transistor T3B having the gate connected to the all-on control terminal AON supplied with the high-level gate all-on control signal GAON becomes the ON-state, and pulls down the node N11. Consequently, the thin film transistor T5 is controlled to become the OFF-state in all-on operation.

Furthermore, the thin film transistor T7 having the gate connected to the all-on control terminal AON supplied with the gate all-on control signal GAON set to the high level is turned on. When the thin film transistor T7 is turned on, the power supply voltage VDD is supplied to the output terminal OUT via the thin film transistor T7, and the signal level at the output terminal OUT is set to the high level by the thin film transistor T7. Here, as described above, the thin film transistors T5, T6 connected to the output terminal OUT are turned off together. Therefore, the signal level at the output terminal OUT is set to the high level by the thin film transistor T7 without being influenced by the thin film transistors T5, T6.

Consequently, the first stage shift register unit circuit 1211 outputs the high-level output signal OUT1.

Among the plurality of shift register unit circuits 121₁, 121₂, 121₃, . . . , 121ₙ, the odd-numbered stage shift register unit circuits in which the gate clock signals GCK1, GCK2 are received the same as the first stage shift register unit circuit 1211 operate in the same manner as the first stage shift register unit circuit 1211 in the all-on operation, and output the high-level output signals. Furthermore, in the even-numbered stage shift register unit circuits, the gate clock signals GCK1, GCK2 received in the clock terminals CK, CKB are inverted to the odd-numbered stage shift register unit circuits, but all of the signal levels of the gate clock signals GCK1, GCK2 are set to the low level during the all-on operation. Therefore, during the all-on operation, the signal levels received in the respective terminals of the even-numbered stage shift register unit circuits are the same as the signal levels received in the respective terminals of the odd-numbered stage shift register unit circuits. Therefore, the all-on operation in the even-numbered stage shift register unit circuits can be described in the same manner as the odd-numbered stage shift register unit circuits, and the even-numbered stage shift register unit circuits output the high-level output signals in the all-on operation.

As described above, the shift register 121 outputs the high-level output signals OUT1, OUT2, . . . , OUTn as the gate signals G1, G2, . . . , Gn, thereby performing the all-on operation.

The all-on operation in the shift register 131 constituting the signal line drive circuit 130 can also be described in the same manner as the shift register 121 constituting the above-described scanning line drive circuit 120.

<Operation when Applied to on-Sequence>

Next, a description will be provided for a case where all-on operation in the shift register 121 is applied to an on-sequence that is to be performed when power of the display device 100 is supplied.

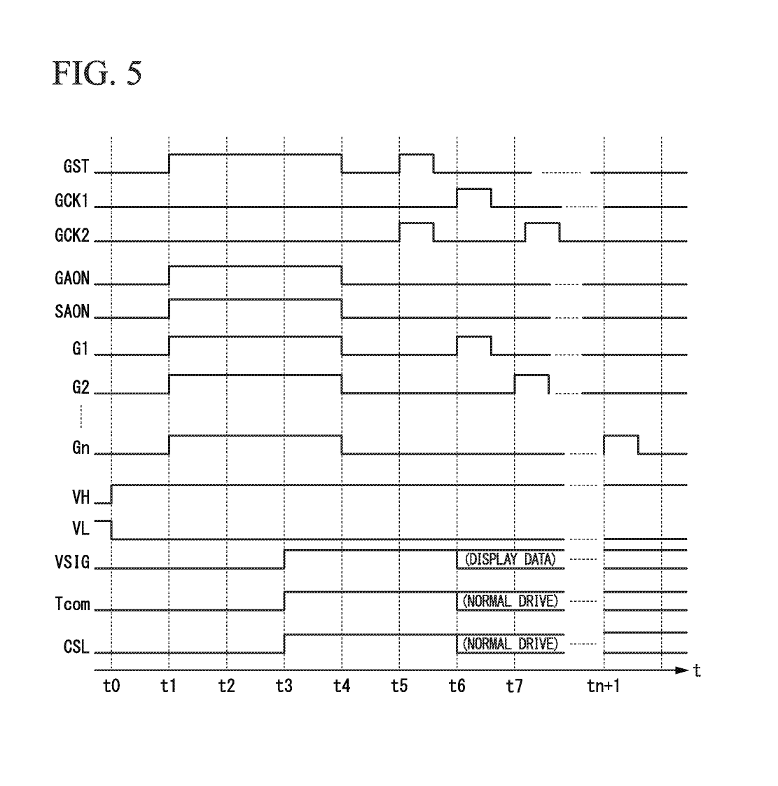

FIG. 5 is a time chart to describe operation in the on-sequence in the display device 100 according to the first embodiment.

Immediately after power is supplied, potential of a video signal line (signal line of a data signal VIG), potential of the counter electrode Tcom, or potential of the auxiliary capacitance electrode line CSL become unstable. Therefore, there may be a case where unintended electric charge is accumulated in a pixel portion PIX. Such a phenomenon is caused by the fact that logic control is not normally performed in the circuit inside the device in the case where the power supply circuit 150 is not surely launched. More specifically, this phenomenon occurs because a potential difference is generated between the counter electrode Tcom and a pixel electrode (not illustrated) and unnecessary electric charge is accumulated in the pixel portion PIX by this potential difference due to the fact that unnecessary electric charge enters the pixel portion PIX from the signal line of the data signal VSIG and the potential of the counter electrode Tcom and the potential of the auxiliary capacitance electrode line CSL become unstable. This phenomenon may cause generation of image noise.

To resolve such a phenomenon, it is effective to instantly release electric charge from all of the pixel portions PIX by making the thin film transistor for a pixel TC conductive in the pixel portion PIX at the time of supplying power. In the case where the electric charge is instantly released from the pixel portions PIX, a change in an image cannot be sensed by the human eye. Therefore, a viewer senses nothing abnormal.

Accordingly, in the on-sequence at the time of supplying power, all-on operation is performed by setting the gate all-on control signal GAON and the source all-on control signal SAON to the active state (high level) at time t1 immediately after power is supplied at time t0. Consequently, the thin film transistors for a pixel TC are made conductive in all of the pixel portions PIX, and initial voltage to display, for example, black is written in the pixel portions PIX as the data signal VSIG. After that, the gate all-on control signal GAON and the source all-on control signal SAON are maintained in the active state, and the gate all-on control signal GAON and the source all-on control signal SAON are set to the inactive state (low level) to stop the all-on operation at time t4 when positive power supply voltage VH (positive high voltage) and negative power supply voltage VL (negative high voltage) generated at the power supply circuit 150 are determined. After that, at time t5, the gate start pulse signal GST and the gate clock signals GCK1, GCK2 are generated, and operation is shifted to the normal operation at time t6. Consequently, the all-on operation is performed in a period immediately after supplying power, during which the power supply voltage is unstable. In this all-on operation, the initial voltage to display black is written in all of the pixel portions PIX, and black is displayed on an entire screen. Consequently, image disturbance at the time of supplying power can be suppressed, and abnormal feeling given to the viewer can be reduced.

Note that the initial voltage of the data signal VSIG is not limited to black and voltage that represents an arbitrary gradation can also be set.

<Operation when Applied to Off-Sequence>

Next, a description will be provided for a case where all-on operation in the shift register 121 is applied in an off-sequence that is to be performed when power of the display device 100 is shut off.

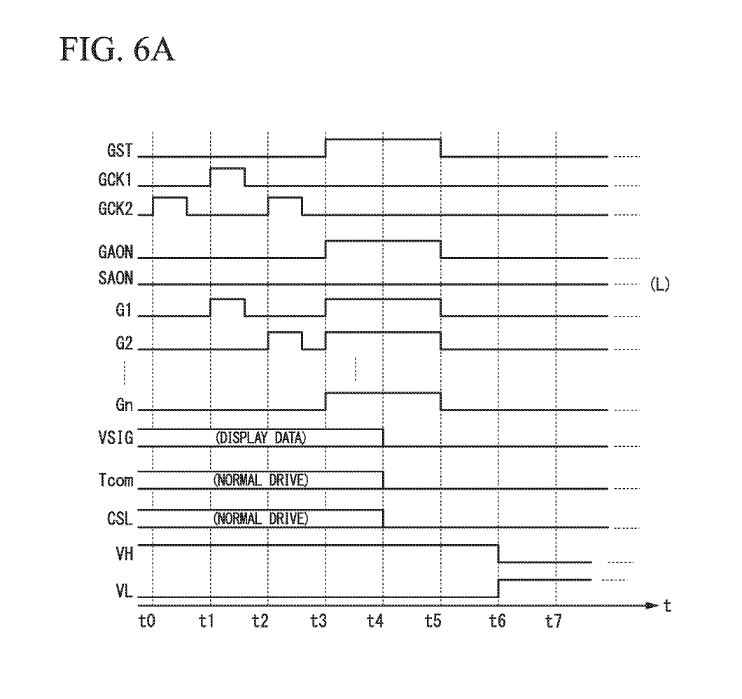

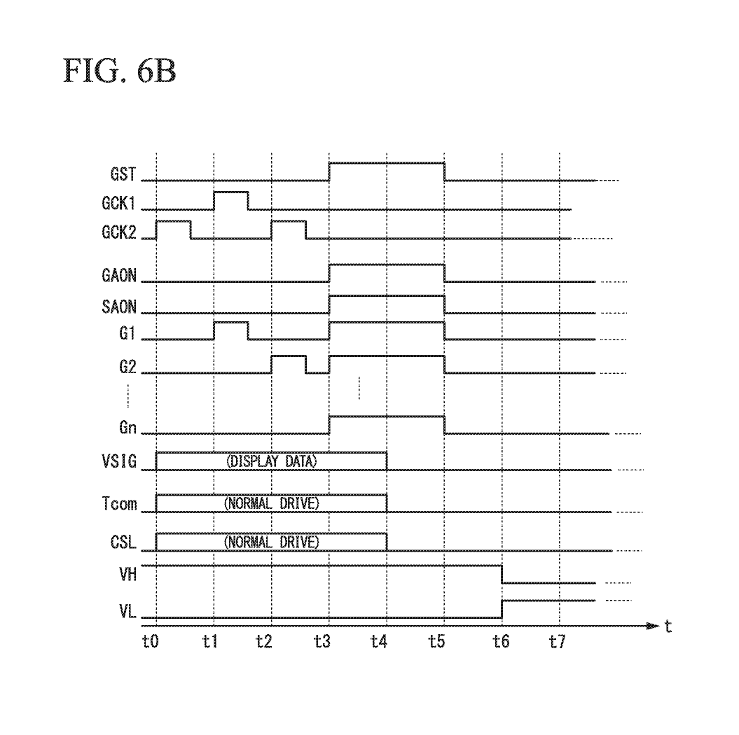

FIGS. 6A and 6B are time charts to describe operation in the off-sequence of the display device 100 according to the first embodiment. FIG. 6A illustrates operation in the case of controlling the scanning line to the high level in the all-on operation, and FIG. 6B illustrates operation in the case of controlling both of the scanning line and the signal line to the high level in the all-on operation.

First, the off-sequence in the case of performing the all-on operation by controlling the scanning line to the high level will be described with reference to FIG. 6A. In this case, the gate all-on control signal GAON is set to the active state, and the source all-on control signal SAON is set to the inactive state. When a command to shut off power supply is supplied to the display device 100 or when such a command is generated inside the display device 100, the gate all-on control signal GAON is set to the high level at time t3 that corresponds to predetermined timing to start the all-on operation. In this case, the shift register 121 of the scanning line drive circuit 120 performs the above-described all-on operation, and all of the gate signals G1, G2, . . . , Gn supplied from the shift register 121 to the scanning lines GL1, GL2, . . . , GLn become the high level. Consequently, the thin film transistors for a pixel TC in all of the pixel portions PIX are made conductive all together.

Here, the display device 100 performs image display operation by, for example, performing dot inversion drive or scanning signal line inversion drive in the normal operation before time t3. Therefore, positive electric charge or negative electric charge is accumulated in each of the plurality of pixel portions PIX connected to the same signal line SL in accordance with content of a display image. In other words, among the plurality of pixel portions PIX connected to the same signal line SL, some of the pixel portions PIX are accumulated with positive electric charge and other pixel portions PIX are accumulated with negative electric charge. Therefore, when all of the thin film transistors for signal line selection TS1, TS2, . . . , TSm illustrated in FIG. 1 are controlled to become the OFF-state at time t3, cancellation of the positive and negative electric charge is performed among the plurality of pixel portions PIX connected to the same signal line SL during the period of all-on operation from t3 to t5. Consequently, when the counter electrode Tcom is shifted to a no-voltage state, operation can be shifted to a finish state in a state that display gradations in all of the pixel portions PIX are substantially uniform. Therefore, gradations in the image displayed by the display device 100 at the time of power shutdown are substantially uniform, and image disturbance can be suppressed.

Next, the off-sequence in the case of performing all-on operation by controlling both of the scanning line and the signal line to the high level will be described with reference to FIG. 6B. In this case, both of the gate all-on control signal GAON and the source all-on control signal SAON are made to become the active state. At time t3 corresponding to predetermined timing to start the all-on operation, both of the gate all-on control signal GAON and the source all-on control signal SAON are made to become the active state, the output signals of the shift register 131 of the signal line drive circuit 130 are controlled to become the high level all together, and further the output signals of the shift register 121 of the scanning line drive circuit 120 are controlled to become the high level all together. Consequently, even when the display device 100 performs any one of AC drive such as dot inversion drive, scanning signal line inversion drive, and data signal line inversion drive in the normal operation before time t3, the respective pixel portions PIX are discharged or charged such that electric charge states in all of the pixel portions PIX are uniformed to a predetermined state in the all-on operation during the period from time t3 to time t5. Therefore, compared to the above-described example illustrated in FIG. 6A, image disturbance can be more stably suppressed at the time of power shutdown.

### <Operation in Forced Shutdown>

Next, a description will be provided for a case where operation of the power supply circuit 150 is forcedly stopped by, for example, power failure in a state that an image is displayed on the display unit of the display device 100.

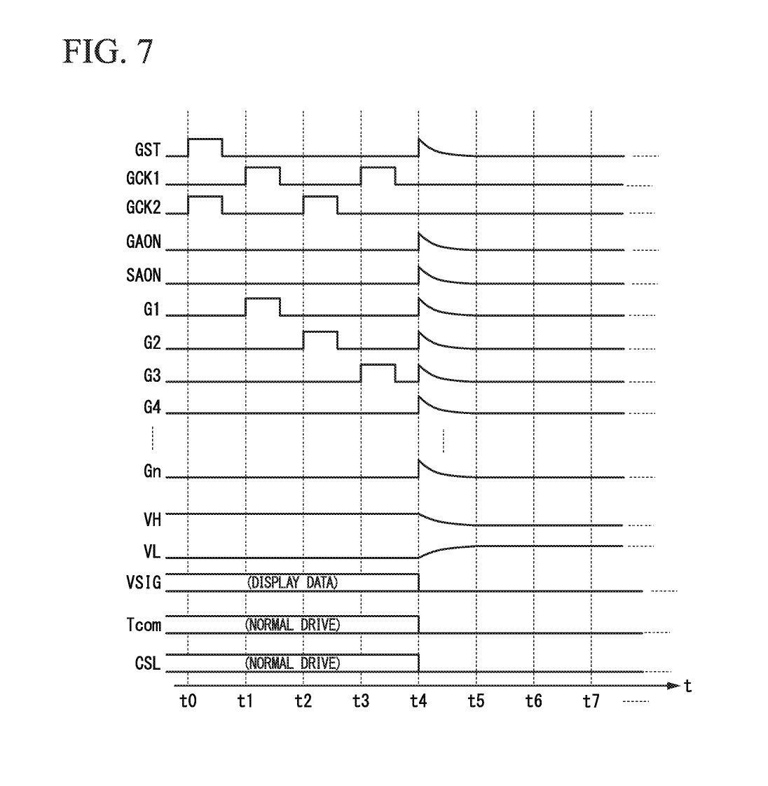

FIG. 7 is a time chart to describe operation at the time of forced shutdown of the display device 100 according to the first embodiment. In the drawing, the scanning line drive circuit 120 performs the normal operation during a period from time t0 to time t3. In this case, the gate all-on control signal GAON and the source all-on control signal SAON are in the inactive state (namely, low level).

When operation of the power supply circuit 150 is forcedly stopped at time t4 in the state of performing such normal operation, the display control circuit 140 sets the gate all-on control signal GAON and the source all-on control signal SAON to the active state (namely, high level) at the same time as when operation of the power supply circuit 150 is stopped. Here, since capacitance C120, C130, and the like are formed on output wiring of the power supply circuit 150, even when operation of the power supply circuit 150 is stopped, the signal levels of the gate all-on control signal GAON and the source all-on control signal SAON output from the display control circuit 140 do not become instantly the ground voltage VSS and are gradually lowered to the ground voltage VSS in accordance with a time constant of capacitance on the output wiring of the power supply circuit 150. In this case, signal levels of other control signals are also lowered in the same manner. Therefore, the gate all-on control signal GAON and the source all-on control signal SAON are relatively maintained in the active state, and the all-on operation is continued even after time t4.

When the gate all-on control signal GAON and the source all-on control signal SAON are set to the active state (high level) at time t4, the shift register 121 of the scanning line drive circuit 120 performs all-on operation and outputs high-level output signals OUT1, OUT2, . . . , OUTn to the scanning lines GL1, GL2, . . . , GLn. In the same manner, the shift register 131 of the signal line drive circuit 130 performs the all-on operation and outputs high-level output signals to the signal lines SL1, SL2, . . . , SLm. At this point, since the capacitance C120, C130, and the like are formed on the output wiring of the power supply circuit 150 as described above, the positive power supply voltage VH output from the power supply circuit 150 does not instantly become a level corresponding to the ground voltage VSS and is gradually decreased to the ground voltage VSS in accordance with the time constant by the capacitance C120, C130 even when operation of the power supply circuit 150 is stopped. In the example of FIG. 7, the positive power supply voltage VH of the power supply circuit 150 starts to be decreased at time t4, and reaches the low level corresponding to the ground potential VSS at time t5. In the same manner, the negative power supply voltage VL output from the power supply circuit 150 does not also instantly become the level corresponding to the ground voltage VSS, and is gradually boosted to the ground voltage VSS in accordance with the time constant by the capacitance C120, C130. Furthermore, the gate signals G1, G2, G3, . . . , Gn on the scanning lines GL1, GL2, . . . , GLn are gradually decreased from time t4 in accordance with decrease of the positive power supply voltage VH output from the power supply circuit 150, and reaches the low level corresponding to the ground voltage VSS at time t5.

Thus, in the case where the power supply circuit 150 is forcedly shut off, all of the signal levels of the scanning lines GL1, GL2, . . . , GLn are instantly made to become the high level by the all-on operation performed by the shift register 121. After that, the signal levels thereof are gradually lowered in accordance with the predetermined time constant. In other words, the signal levels of all of the scanning lines GL1, GL2, . . . , GLn are made to become the same level. Consequently, image disturbance is suppressed and abnormal feeling given to the viewer can be reduced in the same manner as the above-described off-sequence.

According to the above-described first embodiment, NMOS transistors Q6, Q8 specifically provided for cutting off through-current in the above-described related art are not needed. Furthermore, since the node N1 is charged by the one thin film transistor T3A, the number of transistors in the respective shift registers constituting the scanning line drive circuit 120 and the signal line drive circuit 130 can be reduced, and the device structure can be simplified. Therefore, a layout area of the shift registers constituting the scanning line drive circuit 120 and the signal line drive circuit 130 can be reduced, and slim bezel of the display device 100 having the function of all-on operation can be achieved.

Moreover, according to the first embodiment, only the gate all-on control signal GAON is used as a control signal to control the all-on operation without using a gate all-on control signal GAONB that is an inverted signal of the gate all-on control signal GAON. Therefore, the number of terminals, the number of signals, and the number of wires to control the all-on operation can be reduced, and slimmer bezel can be achieved.

Furthermore, according to the first embodiment, the thin film transistor T1 (FIG. 3) is turned off during the all-on operation. Therefore, a through-current path formed by the thin film transistor T1, the resistance R1, and the thin film transistor T2 is cut off. Furthermore, since the thin film transistor T4 is turned off during the all-on operation, a through-current path formed by the thin film transistor T3A and the thin film transistor T4 is cut off. Moreover, since the thin film transistors T5, T6 are turned off together during the all-on operation, a through-current path formed by these thin film transistors T5, T6 is cut off as well. Therefore, according to the present embodiment, through-current in the shift register can be prevented during the all-on operation.

Furthermore, according to the first embodiment, the input signal received in the set terminal SET and set to the high level is supplied to the gate of the thin film transistor T5 via the one thin film transistor T3A during the normal operation. Therefore, the gate voltage decrease at the thin film transistor T5 can be minimized. In other words, since the node N1 is charged by the one thin film transistor T3A, voltage decrease caused by the threshold voltage Vth of the transistor can be minimized and an operation margin can be improved. Therefore, shift operation of the shift register can be stabilized during the normal operation.

Meanwhile, in the above-described examples, the signal levels are set to the high level when the signal levels of the gate all-on control signal GAON and the source all-on control signal SAON become active, but considering that all of the signals are converged to the low level (ground voltage VSS) at the time of power failure, the signal levels may be set to the low level when the signal levels of the gate all-on control signal GAON and the source all-on control signal SAON become active. In this case, the signal levels of the gate all-on control signal GAON and the source all-on control signal SAON are set to the high level during the normal operation, and the signal levels of the gate all-on control signal GAON and the source all-on control signal SAON are set to the low level at the time of forced shutdown. Therefore, the all-on operation can be maintained stable after forced shutdown.

### Second Embodiment

Next, a second embodiment of the present invention will be described.

In the second embodiment, FIGS. 1 and 2 used in the first embodiment will be referenced.

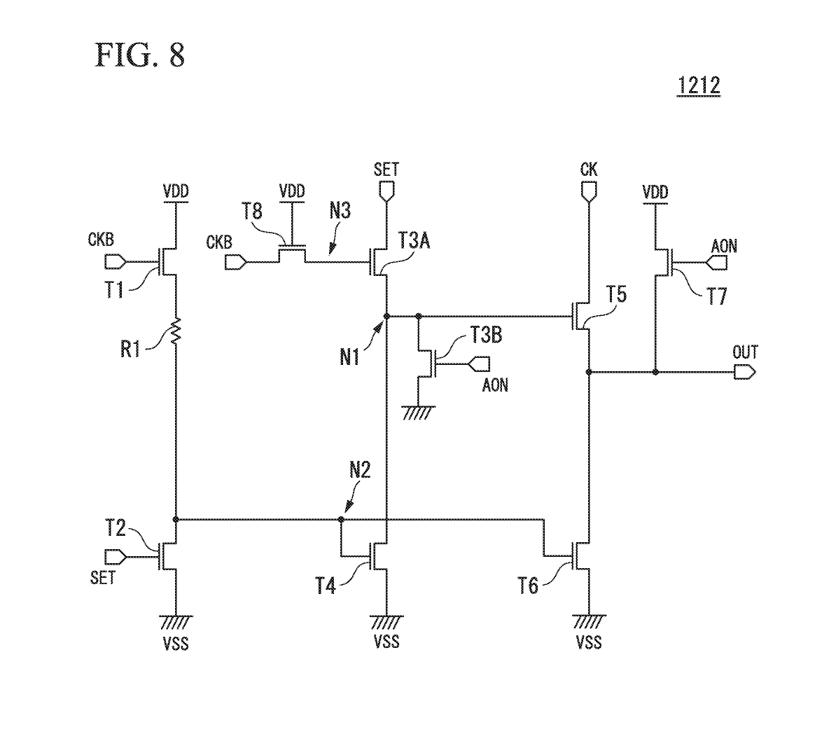

A display device according to the second embodiment includes a shift register unit circuit 1212 illustrated in FIG. 8 instead of shift register unit circuits 1211, 121₂, 121₃, . . . , 121ₙ (namely, shift register unit circuit 1211 illustrated in FIG. 3) constituting the shift register 121 illustrated in FIG. 2 in the above-described first embodiment. Other configurations are the same as the first embodiment.

FIG. 8 is a circuit diagram illustrating an exemplary configuration of the shift register unit circuit 1212 according to the second embodiment. The shift register unit circuit 1212 further includes a thin film transistor T8 in a configuration of the shift register unit circuit 1211 according to the first embodiment illustrated in FIG. 3. The thin film transistor T8 has a current path interposed between a clock terminal CKB and a gate of a thin film transistor T3A, and has the gate applied with power supply voltage VDD (predetermined potential) to supply a signal level adapted to turn on the thin film transistor T8. A node N3 is formed at a connection point between the current path of the thin film transistor T8 and the gate of the thin film transistor T3A. Other configurations are the same as the shift register unit circuit 1211 according to the first embodiment.

Meanwhile, in the present embodiment, each of the shift register unit circuits 121₁, 121₂, 121₃, . . . , 121ₙ according to the first embodiment illustrated in FIG. 2 can be replaced by the shift register unit circuit 1212 illustrated in FIG. 8, but the wordings “shift register unit circuits 121₁, 121₂, 121₃, . . . , 121ₙ” illustrated in FIG. 2 are referenced as they are for sake of description. Therefore, according to the present embodiment, each of the “shift register unit circuits 121₁, 121₂, 121₃, . . . , 121ₙ” represents the shift register unit circuit 1212 illustrated in FIG. 8. The same is applied to respective embodiments described later except for an eighth embodiment.

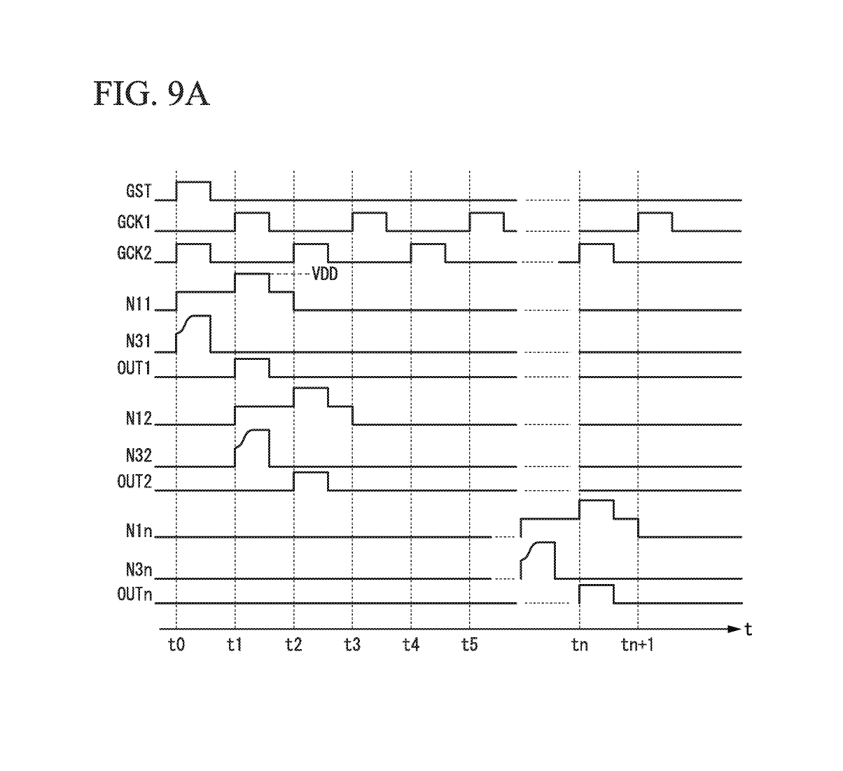

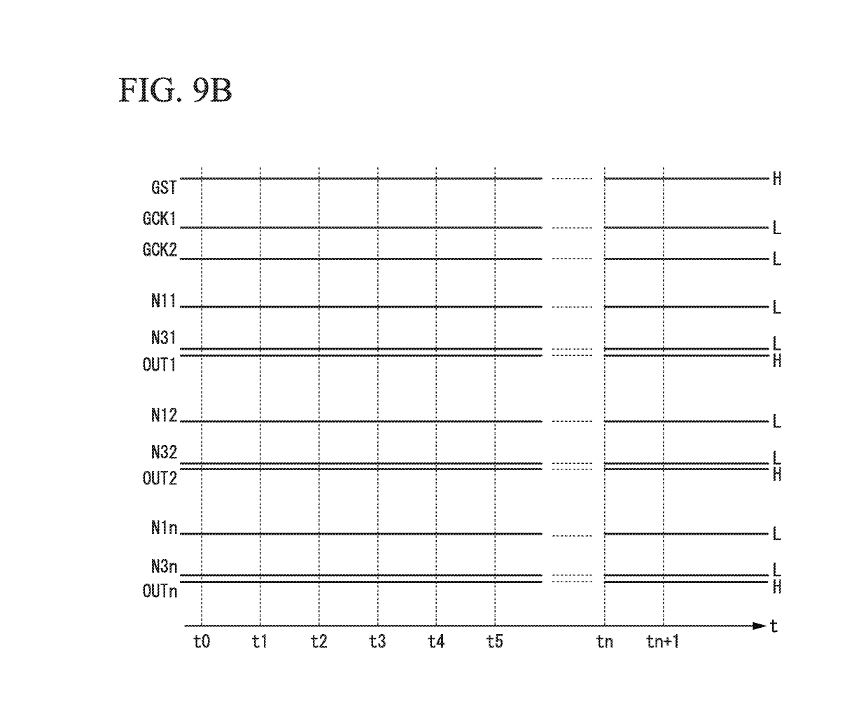

Next, operation of the shift register 1212 will be described with reference to FIGS. 9A and 9B.

FIGS. 9A and 9B are time charts illustrating exemplary operation of the shift register 1212 according to the second embodiment. FIG. 9A is a time chart during normal operation and FIG. 9B is a time chart during all-on operation. Furthermore, in FIGS. 9A and 9B, N11 and N31 represent the nodes N1 and N3 of a first stage shift register unit circuit 121₁, N12 and N32 represent the nodes N1 and N3 of a second stage shift register unit circuit 121₂, N1n and N3n represent the nodes N1 and N3 of an n^{th} stage shift register unit circuit 121ₙ, and OUT1, OUT2, OUTn represent output signals of the first, second, n^{th} stage shift register unit circuits.

Note that “H” in the drawings represents a high level and “L” represents a low level.

First, the normal operation of the shift register 1212 will be described with reference to FIG. 9A.

As illustrated in FIG. 9A, when a clock signal GCK2 received in a clock terminal CKB of the first stage shift register unit circuit 121₁ (namely, the first stage shift register unit circuit 1212) is changed to the high level at time t0, a signal level of this clock signal GCK2 is transmitted to the gate of the thin film transistor T3A via the thin film transistor T8. Consequently, the node N31 between the gate of the thin film transistor T3A and the thin film transistor T8 is charged, and voltage at the node N31 starts to be boosted.

When the voltage at the node N31 is boosted, the thin film transistor T3A is turned on. Here, a gate start pulse signal GST is supplied to a set terminal SET connected to the drain of the thin film transistor T3A as an input signal set to the high level. Therefore, when the thin film transistor T3A is turned on, source voltage thereof is made to a decreased voltage from the gate voltage by threshold voltage Vth. Therefore, the node Nl1 connected to the source of the thin film transistor T3A is charged following the node N31 connected to the gate of the thin film transistor T3A, and the voltage at the node N11 starts to be boosted.

Furthermore, the voltage at the node N31 reaches a decreased voltage from gate voltage at the thin film transistor T8 (power supply voltage VDD) by threshold voltage Vth of the thin film transistor T8, the thin film transistor T8 is turned off and the node N31 becomes a floating state. After that, in the process in which the node N11 is charged by the thin film transistor T3A and the voltage at the node N11 is boosted, the voltage at the node N31 is pushed up by the voltage at the N1 via a capacitance component and the like provided between the source and the gate of the thin film transistor T3A and a capacitance component and the like provided between a channel and the gate of the thin film transistor T3A.

Here, the larger the capacitance component accompanying the node N11, for example, gate capacitance and the like of a transistor T5 is, the more slowly the voltage at the node N11 is boosted by the charging of the thin film transistor T3A, and the voltage at the node N11 starts to be boosted after the node N31 becomes the floating state. In this case, since a boosted amount of the voltage at the node N11 is large, a boosted amount of the voltage at the node N31 pushed up by the voltage at the node N11 is increased as well. When the voltage at the node N31 is boosted by this and reaches voltage equal to or higher than voltage obtained by adding the threshold voltage Vth of the thin film transistor T3A to the high level (power supply voltage VDD) of the gate start pulse signal GST, the node N11 is charged up to the power supply voltage VDD by the thin film transistor T3A without voltage drop caused by the threshold voltage Vth of the thin film transistor T3A.

After that, when the gate clock signal GCK2 received in the clock terminal CKB is changed from the high level to the low level, the thin film transistor T8 having one end of the current path connected to the clock terminal CKB becomes an ON-state. Therefore, the node N31 is discharged by the thin film transistor T8, and a signal level at the node N31 becomes the low level. When the signal level at the node N31 becomes the low level, the thin film transistor T3A having the gate connected to the node N31 is turned off. At this point, the node N11 becomes a floating state and is maintained in a state of being charged by the power supply voltage VDD. Therefore, the thin film transistor T5 having the gate connected to the node N11 is maintained in the ON-state. Subsequently, when the gate clock signal GCK1 received in the clock terminal CK is changed to the high level at time t1, the signal level (high level) of this gate clock signal GCK1 is transmitted to the output terminal OUT via the thin film transistor T5 and the high level is output as an output signal OUT1. Other operations are the same as the shift register 1211 according to the first embodiment.

As illustrated in FIG. 9B, all-on operation is the same as the above-described first embodiment.

In other words, a gate all-on control signal GAON is set to the high level in the all-on operation. Furthermore, as illustrated in FIG. 9B, the gate start pulse signal GST is set to the high level and the gate clock signals GCK1, GCK2 are set to low level. In this case, in the first stage shift register unit circuit 1211, the thin film transistor T1 is turned off and the thin film transistor T2 is turned on. Consequently, the node N21 is pulled down by the thin film transistor T2, and the signal level becomes the low level. As a result, the thin film transistors T4, T6 each having the gate connected to the node N21 are turned off together.

Furthermore, the clock terminal CKB in which the gate clock signal GCK2 set to the low level is received is supplied to the gate of the thin film transistor T3A via the thin film transistor T8, thereby turning off the thin film transistor T3A. Therefore, the gate start pulse signal GST received in the set terminal SET as the input signal set to the high level is not transmitted to the node N11. In this case, a thin film transistor T3B connected between the node N11 and a ground node is turned on. Consequently, the node N11 becomes the low level and the thin film transistor T5 having the gate connected to the node N11 is turned off.

Furthermore, the thin film transistor T7 having the gate connected to the all-on control terminal AON supplied with the gate all-on control signal GAON set to the high level is turned on. When the thin film transistor T7 is turned on, the power supply voltage VDD is supplied to the output terminal via the thin film transistor T7, thereby setting the output terminal OUT to the high level. Here, the thin film transistors T5, T6 connected to the output terminal OUT become the OFF-state together. Therefore, the output terminal OUT is set to the high level by the thin film transistor T7 without receiving any influence from the thin film transistors T5, T6. Consequently, the first stage shift register unit circuit 121₁ outputs the high-level output signal OUT1. Output signals OUT2, OUT3, . . . , OUTn of the second and subsequent stage shift register unit circuits 121₂, 121₃, . . . , 121ₙ, are also set to the high level in the same manner as the output signal OUT1 of the first stage shift register unit circuit 121₁.

In the above-described manner, the scanning line drive circuit 120 formed of the shift register unit circuits 1212 according to the present embodiment outputs the high-level output signals OUT1, OUT2, . . . , OUTn as gate signals G1, G2, . . . , Gn, and the all-on operation is performed.

According to the second embodiment, the gate voltage at the thin film transistor T3A is higher compared to the first embodiment. Due to this, waveform distortion of a signal transmitted via the thin film transistor T3A can be suppressed. Therefore, even when the threshold voltage Vth of the thin film transistor is boosted by receiving, for example, influence of initial characteristics, temperature characteristics, deterioration, and so on, deterioration of the signal inside the shift register can be suppressed and an operation margin of the shift register can be improved.

### Third Embodiment

Next, a third embodiment of the present invention will be described.

In the present embodiment, FIGS. 1 and 2 used in the first embodiment will also be referenced.

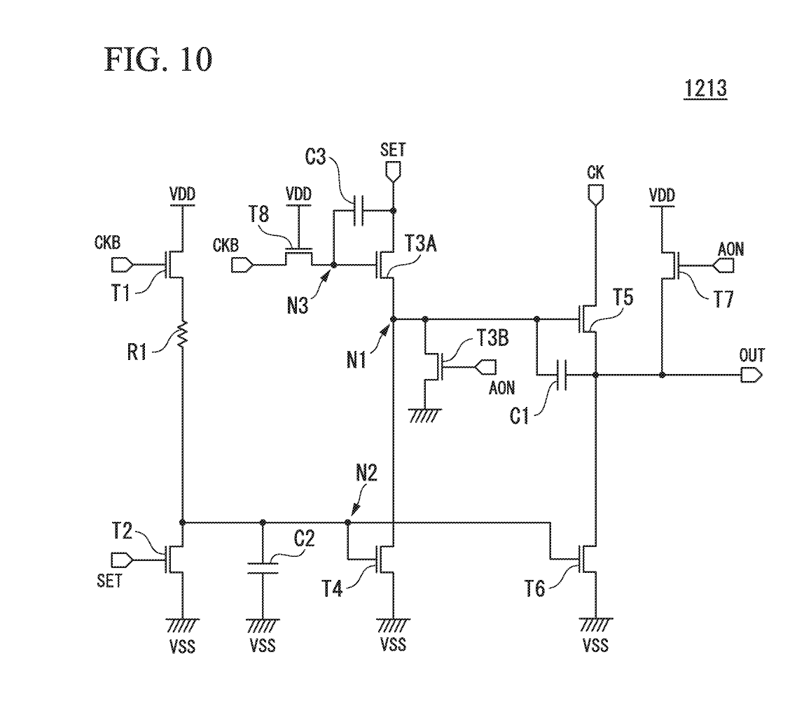

A display device according to the third embodiment includes a shift register unit circuit 1213 illustrated in FIG. 10 instead of shift register unit circuits 121₁, 121₂, 121₃, . . . , 121ₙ (namely, shift register unit circuit 1211 illustrated in FIG. 3) constituting a shift register 121 illustrated in FIG. 2 referenced in the second embodiment described above. Other configurations are the same as the second embodiment.

FIG. 10 is a circuit diagram illustrating an exemplary configuration of the shift register unit circuit 1213 according to the third embodiment. The shift register unit circuit 1213 further includes capacitors C1, C2, C3 in a configuration of the shift register unit circuit 1212 illustrated in FIG. 8 according to the second embodiment.

The capacitor C1 is connected between a drain and a gate of a thin film transistor T5. The capacitor C3 is connected between a drain and a gate of a thin film transistor T3A. The capacitor C2 is connected between ground node (predetermined potential node) and a node N2 connected to respective gates of thin film transistors T4, T6. Other configurations are the same as the shift register unit circuit 1212 according to the second embodiment.

Note that all of the capacitors C1, C2, C3 are not necessarily provided, and any one or two of the capacitors may be provided.

Basic operation is the same as the shift register unit circuit 1212 in the above-described second embodiment, but in the present embodiment, a self-bootstrap effect in the thin film transistor T5 can be improved by the capacitor C1 in normal operation. Due to this, when the thin film transistor T5 is turned on, gate voltage at the thin film transistor T5 can be effectively boosted.

Therefore, a signal level can be transmitted to an output terminal OUT without impairing the signal level to be transmitted to the output terminal OUT from a clock terminal CK via the thin film transistor T5.

Furthermore, a bootstrap effect in the thin film transistor T3A can be improved by the capacitor C3. Consequently, gate voltage at the thin film transistor T3A can be effectively boosted when an input signal supplied to a set terminal SET is changed to a high level and the thin film transistor T3A is turned on. Therefore, a signal level can be transmitted from the set terminal SET to a node N1 via the thin film transistor T3A without impairing the signal level.

Furthermore, voltage-maintaining ability at the node N2 can be improved by the capacitor C2. Due to this, the thin film transistors T4, T6 can be stably maintained in an OFF-state while the node N1 is charged, and shift operation can be stabilized.

According to the present embodiment, a voltage-boosting amount at the node N1 or node N3 can be further improved by the bootstrap effect, compared to the second embodiment. Therefore, the thin film transistors T3A, T5 can be stably controlled to become an ON-state. Therefore, an operation margin of the shift register can be improved.

Note that all-on operation is performed in the same manner as the above-described first and second embodiments.

### Fourth Embodiment

Next, a fourth embodiment of the present invention will be described.

In the present embodiment, FIGS. 1 and 2 used in the first embodiment will also be referenced.

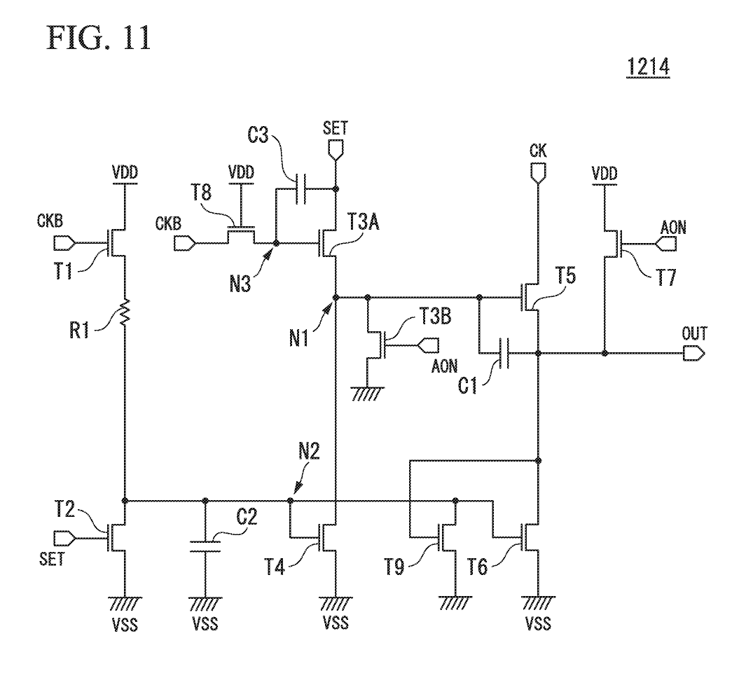

A display device according to the fourth embodiment includes a shift register unit circuit 1214 illustrated in FIG. 11 instead of shift register unit circuits 121₁, 121₂, 121₃, . . . , 121ₙ (namely, shift register unit circuit 1211 illustrated in FIG. 3) constituting a shift register 121 illustrated in FIG. 2 referenced in the third embodiment described above. Other configurations are the same as the third embodiment.

FIG. 11 is a circuit diagram illustrating an exemplary configuration of the shift register unit circuit 1214 according to the fourth embodiment. The shift register unit circuit 1214 further includes a thin film transistor T9 in a configuration of a shift register unit circuit 1213 illustrated in FIG. 10 according to the third embodiment. The thin film transistor T9 has a gate connected to a drain of a thin film transistor T6, a drain connected to a gate of the thin film transistor T6, and a source connected to a ground node (predetermined potential node). In other words, the thin film transistor T6 and the thin film transistor T9 have the gates and drains cross-connected to each other. Other configurations are the same as the shift register unit circuit 1213 according to the third embodiment.

Basic operation is the same as the shift register unit circuits 1212 in the above-described third embodiment, but in the present embodiment, an output signal from an output terminal OUT can be stably maintained at a high level during a period from time t1 to time t2 illustrated in FIG. 9A according to the above-described second embodiment. This will be described with reference to a time chart in FIG. 9A. In normal operation, when a gate start pulse signal GST and a gate clock signal GCK2 are changed to the high level at time t0, thin film transistors T1, T2 become an ON-state as described above, and a node N2 is driven to a low level by the thin film transistor T2 out of the thin film transistors. After that, when the gate start pulse signal GST and the gate clock signal GCK2 are changed to the low level, the thin film transistors T1, T2 become an OFF-state and the node N2 becomes a floating state. Consequently, the signal level (namely, low level) maintained till then at the node N2 is maintained by capacitance (for example, capacitance of a capacitor C2 or the like) formed at the node N2. Furthermore, when the gate clock signal GCK1 is changed to the high level at time t1, the high level is output to the output terminal OUT via a thin film transistor T5 as described above.

Here, while the high level is output to the output terminal OUT via the thin film transistor T5 from time t1, the thin film transistor T6 needs to be maintained in the OFF-state. Regarding this point, according to the first to third embodiments, the node N2 connected to the gate of the thin film transistor T6 is maintained in the floating state while the output signal of the output terminal OUT is changed to the high level at time t1. Accordingly, a signal level at the gate of the thin film transistor T6 is maintained at the low level by the capacitance formed at the node N2 and the signal level is in an unstable state. Therefore, when the signal level at the node N2 is raised due to noise and existence of a leak path, for example, there may be a possibility that the thin film transistor T6 becomes the ON-state and the signal level (high level) at the output terminal OUT is lowered.

On the other hand, according to the forth embodiment, when the signal level at the output terminal OUT is changed to the high level due to the above-mentioned noise and existence of the leak path, a signal level at the gate of the thin film transistor T9 becomes the high level. Therefore, the thin film transistor T9 becomes the ON-state and drives the node N2 connected to the gate of the thin film transistor T6 to the low level (ground voltage VSS). Consequently, the thin film transistor T6 is forcedly maintained in the OFF-state by the thin film transistor T9 while the signal level at the output terminal OUT is maintained at the high level from time t1. Therefore, according to the present embodiment, the output signal can be stably maintained at the high level in the normal operation, and malfunction caused by a lowered signal level of the output signal can be prevented.

Therefore, an operation margin of the shift register can be improved.

Note that all-on operation is performed in the same manner as the above-described first to third embodiments.

### Fifth Embodiment

Next, a fifth embodiment of the present invention will be described.

In the present embodiment, FIGS. 1 and 2 used in the first embodiment will also be referenced.

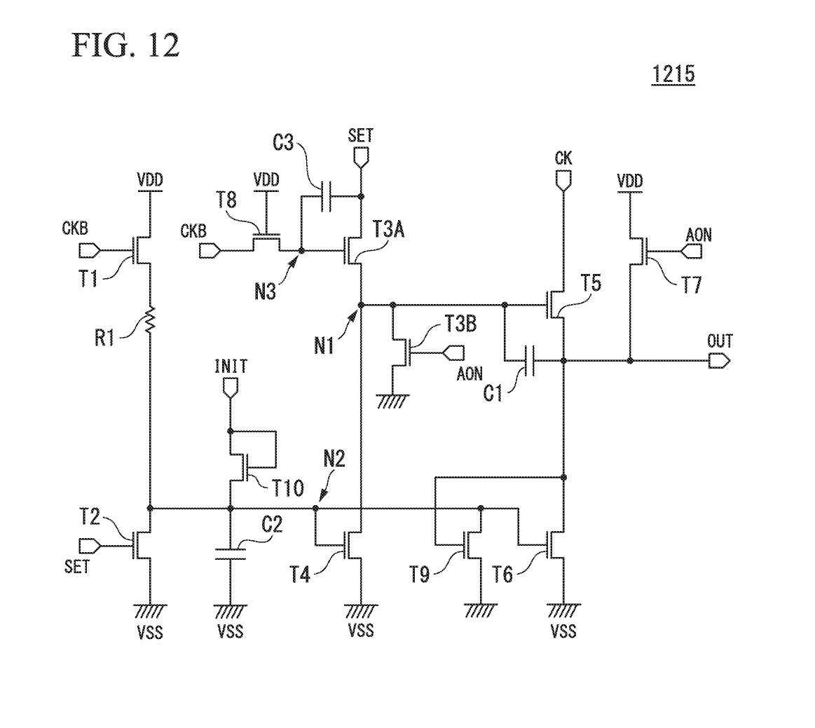

A display device according to the fifth embodiment includes a shift register unit circuit 1215 illustrated in FIG. 12 instead of shift register unit circuits 121₁, 121₂, 121₃, . . . , 121ₙ, (namely, shift register unit circuit 1211 illustrated in FIG. 3) constituting a shift register 121 illustrated in FIG. 2 referenced in the fourth embodiment described above. Other configurations are the same as the fourth embodiment.

FIG. 12 is a circuit diagram illustrating an exemplary configuration of the shift register unit circuit 1215 according to the fifth embodiment. The shift register unit circuit 1215 further includes a thin film transistor T10 in a configuration of a shift register unit circuit 1214 according to the fourth embodiment illustrated in FIG. 11. The thin film transistor T10 has a source connected to a node N2 connected to respective gates of a thin film transistor T6 and a thin film transistor T4, and has a gate and a drain applied with an initialization signal INIT. In other words, the thin film transistor T10 is diode-connected, in which a node corresponding to an anode is supplied with the initialization signal INIT and a node corresponding to a cathode is connected to the node N2 connected to the respective gates of the thin film transistors T4, T6.

Other configurations are the same as the shift register unit circuit 1214 according to the fourth embodiment.

The initialization signal INIT is a signal to be set to an active state (high level) by, for example, a display control circuit 140 at the time of supplying power and stopping power supply, or in the case of once initializing the shift register. Note that the initialization signal INIT is set to an inactive state (low level) in all-on operation. When the initialization signal INIT is made to become the active state, voltage at the drain and the gate of the thin film transistor T10 is boosted, and a decreased voltage from the drain voltage by threshold voltage Vth is generated at the source of the thin film transistor T10. For example, in the case where the high level of the initialization signal INIT is power supply voltage VDD, the voltage (VDD−Vth) decreased from the power supply voltage VDD by the threshold voltage Vth of the thin film transistor T10 is generated at the source of the thin film transistor T10. When this source voltage (VDD−Vth) at the thin film transistor T10 is supplied to the node N2, the thin film transistors T4, T6 are forcedly turned on. Due to this, a node N1 is discharged by the thin film transistor T4 and further an output terminal OUT is pulled down by the thin film transistor T6. As a result, a circuit state of the shift register unit circuit 1215 is initialized, and further a signal level of an output signal is initialized to the low level.

According to the present embodiment, the circuit state of the shift register can be configurationally initialized regardless of signals received in clock terminals CK, CKB, a set terminal SET, and so on by controlling the initialization signal INIT to be the active state. Furthermore, the shift register can be stably controlled to become the inactive state and further the output signal can be set to the low level.

Additionally, in the present embodiment, the thin film transistor T10 is configured to have the diode connection, but the thin film transistor T10 may also have a configuration in which the voltage at the drain is fixed to the power supply voltage VDD and the initialization signal INIT is received in this gate.

Note that the all-on operation is performed in the same manner as the above-described first to fourth embodiments.

### Sixth Embodiment

Next, a sixth embodiment of the present invention will be described.

In the present embodiment, FIGS. 1 and 2 used in the first embodiment will also be referenced.

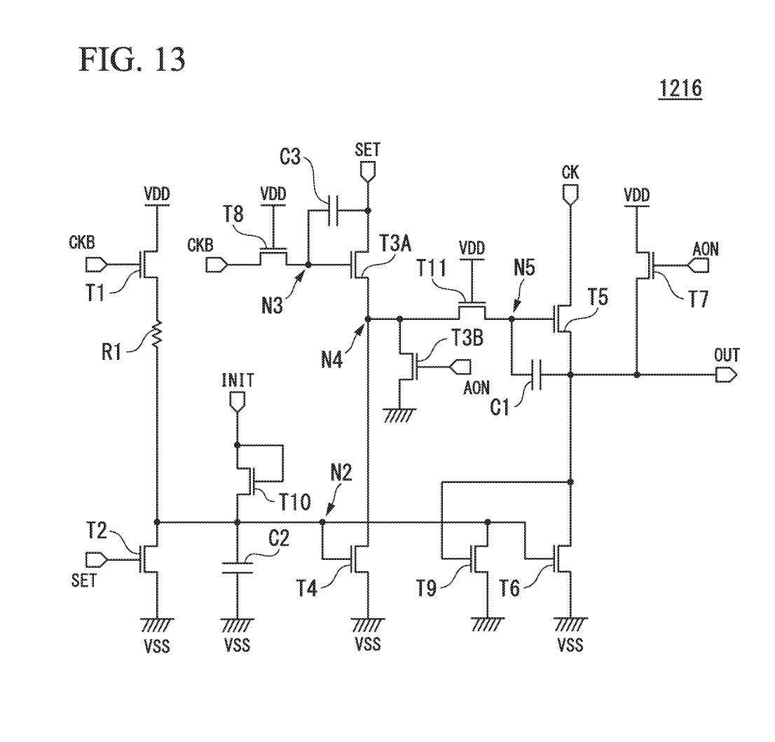

A display device according to the sixth embodiment includes a shift register unit circuit 1216 illustrated in FIG. 13 instead of shift register unit circuits 121₁, 121₂, 121₃, . . . , 121ₙ (namely, shift register unit circuit 1211 illustrated in FIG. 3) constituting a shift register 121 illustrated in FIG. 2 referenced in the fifth embodiment described above. Other configurations are the same as the fifth embodiment.

FIG. 13 is a circuit diagram illustrating an exemplary configuration of the shift register unit circuit 1216 according to the sixth embodiment. The shift register unit circuit 1216 further includes a thin film transistor T11 in a configuration of a shift register unit circuit 1215 according to the fifth embodiment illustrated in FIG. 12. The thin film transistor T11 has a current path interposed between a drain of a thin film transistor T3A and a gate of a thin film transistor T5. More specifically, one of a source and a drain forming the current path of the thin film transistor T11 is connected to a source of the thin film transistor T3A, and the other one of the source and the drain of the thin film transistor T11 is connected to the gate of the thin film transistor T5. The thin film transistor T11 has a gate applied with power supply voltage VDD (predetermined potential). In the present embodiment, a node N4 is formed at a connection point between the source of the thin film transistor T3A and a drain of a thin film transistor T4, and a node N5 is formed at a connection point between the current path of the thin film transistor T11 and the gate of the thin film transistor T5. Other configurations are the same as the shift register unit circuit 1215 according to the fifth embodiment.

According to the shift register unit circuit 1215 in the above-described fifth embodiment, when voltage at a node N1 is pushed up due to a bootstrap effect by a capacitor C1, the voltage thereof is boosted to voltage (VDD+α) higher than the power supply voltage VDD. At this point, along with the bootstrap effect by a capacitor C3, a differential voltage between the high voltage (VDD+α) and ground voltage VSS is applied between the gate and the drain and between the source and the drain of the thin film transistor T3A, and extremely high voltage is applied. The same phenomenon occurs in a thin film transistor T4 as well, and the differential voltage between the high voltage (VDD+α) and the ground voltage VSS is also applied between a gate and the drain and between a source and the drain of the thin film transistor T4. Such high voltage may become a cause of, for example, deterioration and the like of a transistor. According to the sixth embodiment, the above-described high voltage generation in the fifth embodiment is prevented by the thin film transistor T11 in operation of the shift register unit circuit 1216 as described next.

Operation of the shift register unit circuit 1216 according to the present embodiment will be described.

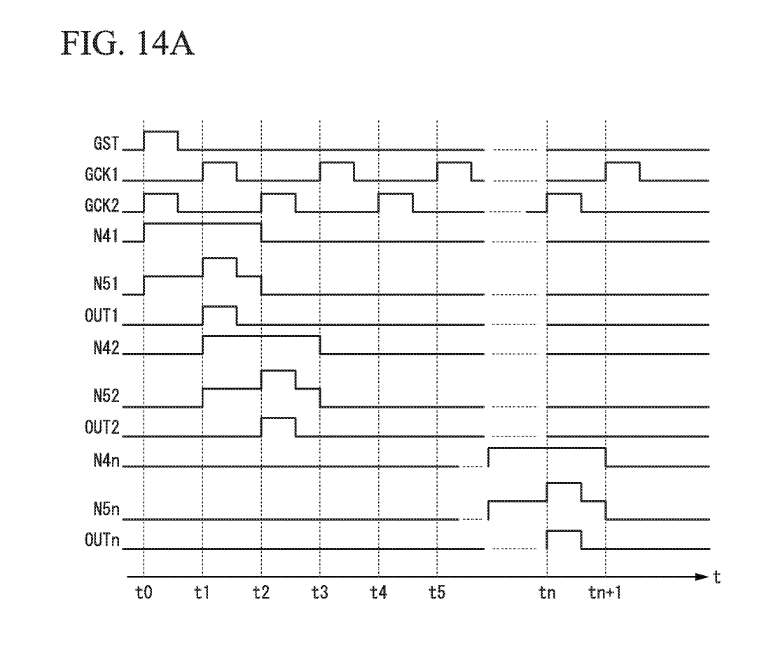

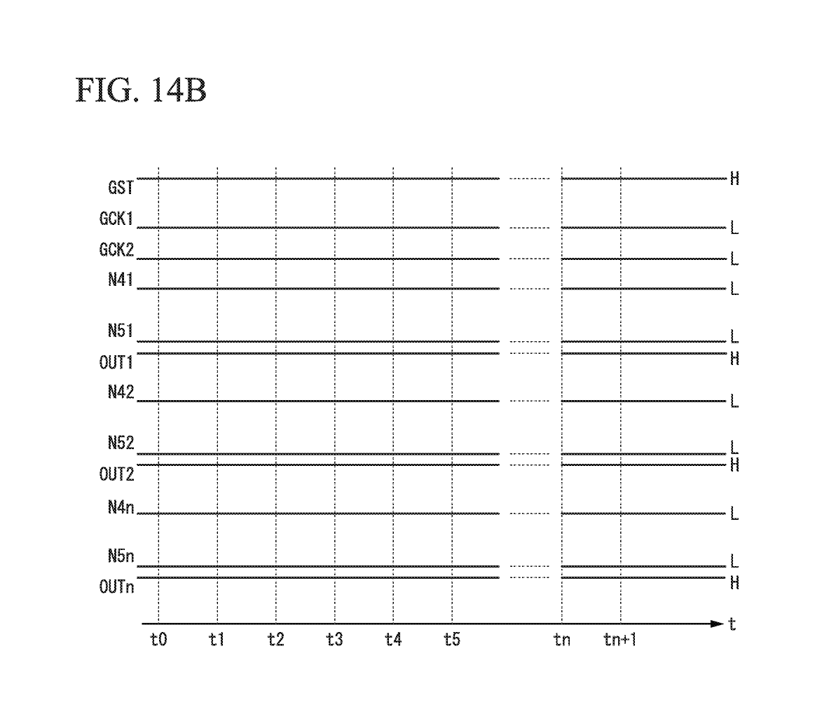

FIGS. 14A and 14B are time charts illustrating exemplary operation of the shift register 121 including the shift register unit circuit 1216 according to the sixth embodiment. FIG. 14A is a time chart during normal operation and FIG. 14B is a time chart during all-on operation. In FIGS. 14A and 14B, a high level and a low level of a gate start pulse signal GST and gate clock signals GCK1, GCK2 are signal levels corresponding to the operation power supply voltage VDD supplied to the shift register and the ground voltage VSS respectively. Furthermore, in the normal operation, a gate all-on control signal GAON is set to the low level. Additionally, in FIGS. 14A and 14B, N41 and N51 represent the nodes N4 and N5 of the first stage shift register unit circuit 121₁, N42 and N52 represent the nodes N4 and N5 of the second stage shift register unit circuit 121₂, N4n and N5n represent the nodes N4 and N5 of the n^{th} stage shift register unit circuit 121ₙ, OUT1, OUT2, and OUTn represent output signals of the first, second, n^{th} stage shift register unit circuits respectively.

Note that “H” in the drawings represents the high level and “L” represents the low level.

First, the normal operation of the shift register 1216 will be described with reference to FIG. 14A.

Basic operation of the shift register unit circuit 1216 is the same as the normal operation of respective shift register unit circuits 1216 in the above-described first to fifth embodiments, but the sixth embodiment differs from the above-described respective embodiments in having different behavior of an internal signal when the node N4 is charged and the high level is output as an output signal.

As illustrated in FIG. 14A, when a gate clock signal GCK2 received in a clock terminal CKB of the first stage shift register unit circuit 1211 (namely, the first stage shift register unit circuit 1216) is changed to the high level at time t0, a signal level of this gate clock signal GCK2 is transmitted to the gate of the thin film transistor T3A via the thin film transistor T8. Consequently, the node N31 between the gate of the thin film transistor T3A and the thin film transistor T8 is charged, and voltage at the node N31 starts to be boosted.

When the voltage at the node N31 is boosted, the thin film transistor T3A is turned on. Here, the gate start pulse signal GST set to the high level is supplied to a set terminal SET connected to the drain of the thin film transistor T3A. Therefore, when the thin film transistor T3A is turned on, source voltage thereof is made to a decreased voltage from the gate voltage thereof by threshold voltage Vth. Therefore, a node N41 connected to the source of the thin film transistor T3A is charged following the node N31 connected to the gate of the thin film transistor T3A, and voltage at the node N41 starts to be boosted.

Furthermore, when the voltage at the node N31 reaches a decreased voltage from the power supply voltage VDD by threshold voltage Vth of the thin film transistor T8, the thin film transistor T8 is turned off and the node N31 becomes a floating state. After that, in a process in which the node N41 is charged by the thin film transistor T3A and the voltage at the node N41 is boosted, the voltage at the node N31 is pushed up by the voltage at the node N41 via coupled capacitance (parasitic capacitance) between the source and the gate of the thin film transistor T3A.

When the voltage at the node N31 is boosted and reaches voltage equal to or higher than voltage obtained by adding the threshold voltage Vth of the thin film transistor T3A to the power supply voltage VDD, the node N41 is charged up to the power supply voltage VDD by the thin film transistor T3A without voltage drop caused by the threshold voltage Vth of the thin film transistor T3A. Here, the power supply voltage VDD is applied to the gate of the thin film transistor T11, and the thin film transistor T11 is in an ON-state. Therefore, when the node N41 is charged, the node N51 is also charged via the thin film transistor T11 and a signal level at the node N51 is raised. Due to this, the thin film transistor T5 having the gate connected to the node N51 is turned on.

However, at this point, a signal level of a gate clock signal CK1 received in the drain of the thin film transistor T5 connected to a clock terminal CK is the low level. Therefore, a signal level of the output signal at an output terminal OUT1 remains at the low level. When the node N5 is charged via the thin film transistor T11 to the decreased voltage from the power supply voltage VDD by threshold voltage Vth of the thin film transistor T11, the thin film transistor T11 is turned off, and node N41 and the node N51 are electrically disconnected.

Subsequently, when the gate clock signal GCK1 received in the clock terminal CK is changed to the high level at time t1, the signal level (high level) of this gate clock signal GCK1 is transmitted to the output terminal OUT via the thin film transistor T5 and the high level is output as an output signal OUT1. At this point, voltage at the node N51 is pushed up to high voltage by the voltage of the output signal of the output terminal OUT due to the bootstrap effect by the capacitor C1. Consequently, the high level (power supply voltage VDD) of the gate clock signal GCK1 received in the clock terminal CK is transmitted to the output terminal OUT without voltage drop caused by the threshold voltage Vth of the thin film transistor T5.

Here, even when the voltage at the node N51 is boosted due to the bootstrap effect by the capacitor C1, the thin film transistor T11 is turned off. Therefore, the voltage at the node N41 is not pushed up due to the bootstrap effect by the capacitor C1, and the voltage at the node N41 is maintained at the power supply voltage VDD. Therefore, according to the present embodiment, only the differential voltage between the power supply voltage VDD and the ground voltage VSS is applied to the thin film transistors T3A, T4, and high voltage is not applied.

Furthermore, the voltage at the node N51 remains at the voltage (VDD−Vth+α) obtained by subtracting the threshold voltage Vth of the thin film transistor T11 from the voltage at the node N41 and then adding the voltage a corresponding to voltage boosted by the capacitor C1. Therefore, only the differential voltage (α−Vth) between the voltage at the node N51 (VDD−Vth+α) and the voltage (VDD) at the node N41 is applied to the thin film transistor T11. Furthermore, the voltage a corresponding to the voltage boosted due to the bootstrap effect by the capacitor C1 does not become larger than amplitude (VDD−VSS) of the gate clock signal GCK1 received in the clock terminal CK. Therefore, only voltage equal to or less than normal drive voltage is applied to the thin film transistor T5 as well.

Other normal operations are the same as the above-described embodiments.

As illustrated in FIG. 14B, the all-on operation is the same as the above-described respective embodiments.

In other words, a gate all-on control signal GAON is set to the high level in the all-on operation. Furthermore, as illustrated in FIG. 14B, the gate start pulse signal GST is set to the high level, and the gate clock signals GCK1, GCK2 are set to the low level. In this case, in the first stage shift register unit circuit 121₁, the thin film transistor T1 is turned off and the thin film transistor T2 is turned on. Consequently, the node N21 is pulled down by the thin film transistor T2, and the signal level becomes the low level. As a result, the thin film transistors T4, T6 each having the gate connected to the node N21 are turned off.

Furthermore, the thin film transistor T3A having the gate connected to the clock terminal CKB in which the gate clock signal GCK2 set to the low level is received is turned off. On the other hand, the thin film transistor T3B having the gate connected to the all-on control terminal AON supplied with the high-level gate all-on control signal GAON becomes the ON-state, and pulls down the node N1. Consequently, the thin film transistor T5 is controlled to become the OFF-state in all-on operation.

Furthermore, a thin film transistor T7 having a gate connected to the all-on control terminal AON supplied with the gate all-on control signal GAON set to the high level is turned on. When the thin film transistor T7 is turned on, the power supply voltage VDD is supplied to the output terminal OUT via the thin film transistor T7, and the output terminal OUT is set to the high level. Consequently, the first stage shift register unit circuit 121₁ outputs the high-level output signal OUT1. Output signals OUT2, OUT3, . . . , OUTn of the second and subsequent stage shift register unit circuits 121₂, 121₃, . . . , 121ₙ are also set to the high level in the same manner as the output signal OUT1 of the first stage shift register unit circuit 121₁.

As described, the shift register 121 formed of the shift register unit circuits 1216 according to the present embodiment outputs the high-level output signals OUT1, OUT2, . . . , OUTn as gate signals G1, G2, . . . , Gn, and the all-on operation is performed.

According to the sixth embodiment, the voltage applied to the respective thin film transistors is further reduced compared to the fifth embodiment. Therefore, the transistors can be prevented from deterioration.

### Seventh Embodiment

Next, a seventh embodiment of the present invention will be described.

In the present embodiment, FIGS. 1 and 2 used in the first embodiment will also be referenced.

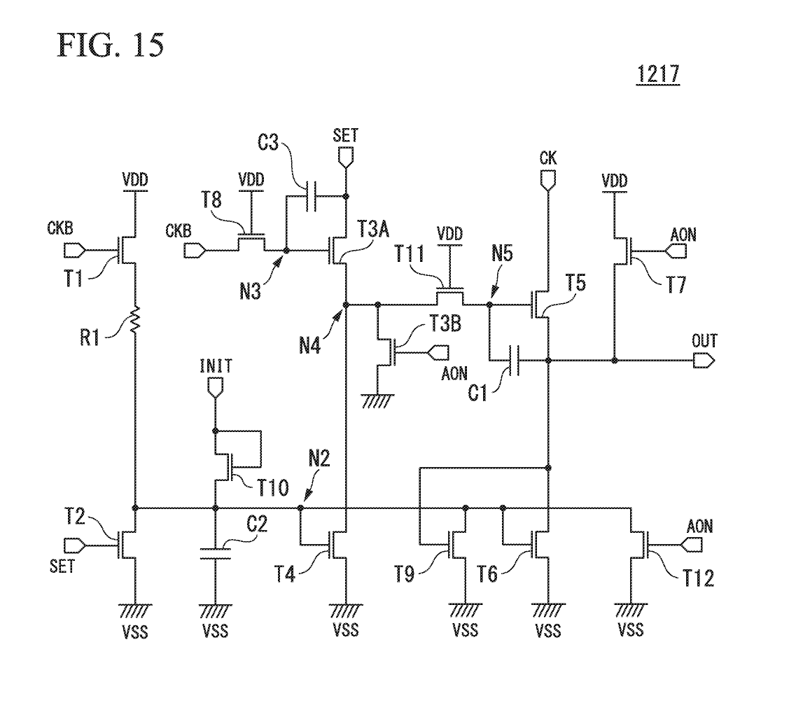

A display device according to the seventh embodiment includes a shift register unit circuit 1217 illustrated in FIG. 15 instead of shift register unit circuits 121₁, 121₂, 121₃, . . . , 121ₙ (namely, shift register unit circuit 1211 illustrated in FIG. 3) constituting a shift register 121 illustrated in FIG. 2 referenced in the sixth embodiment described above. Other configurations are the same as the sixth embodiment.

FIG. 15 is a circuit diagram illustrating an exemplary configuration of the shift register unit circuit 1217 according to the seventh embodiment. The shift register unit circuit 1217 further includes a thin film transistor T12 in a configuration of a shift register unit circuit 1216 according to the sixth embodiment illustrated in FIG. 13. The thin film transistor T12 has a current path connected between a node N2 connected to a gate of a thin film transistor T6 and a ground node (predetermined potential node). Furthermore, the thin film transistor T12 has a gate connected to an all-on control terminal AON, and has the gate applied with an all-on control signal GAON. Other configurations are the same as the shift register unit circuit 1216 according to the sixth embodiment.

Next, operation of the shift register unit circuit 1217 according to the present embodiment will be described.

According to the present embodiment, normal operation is the same as the above-described the sixth embodiment. Therefore, a description therefor will be omitted, and all-on operation will be described.

In the all-on operation, the gate all-on control signal GAON is set to a high level. Furthermore, gate clock signals GCK1, GCK2 are set to a low level. A gate start pulse signal GST may be set to either the high level or the low level.

In the case where the gate start pulse signal GST received in a set terminal SET is the high level, a thin film transistor T2 is turned on and the node N2 is discharged by the thin film transistor T2 in the same manner as the above-described respective embodiments. In this case, since the thin film transistor T12 having the gate connected to the all-on control terminal AON is also turned on, the node N2 is discharged together with the thin film transistor T2 via the thin film transistor T12. Consequently, the thin film transistors T4, T6 each having a gate connected to the node N2 are controlled to become an OFF-state together.

Furthermore, the low level of the gate clock signal GCK2 received in a clock terminal CKB is supplied to a gate of the thin film transistor T3A via a thin film transistor T8. Consequently, the thin film transistor T3A is turned off. On the other hand, the high-level gate all-on control signal GAON is supplied to the all-on control terminal AON connected to a gate of a thin film transistor T3B, thereby turning on the thin film transistor T3B. Consequently, the node N4 is discharged via the thin film transistor T3B. The low level at the discharged node N4 is transmitted to a gate of a thin film transistor T5 via a thin film transistor T11, thereby turning off the thin film transistor T5. As a result, both of the thin film transistors T5, T6 connected to an output terminal OUT are turned off.

In contrast, a thin film transistor T7 having a gate connected to the all-on control terminal AON supplied with the gate all-on control signal GAON set to the high level is turned on. When the thin film transistor T7 is turned on, the power supply voltage VDD is supplied to the output terminal OUT via the thin film transistor T7, and the output terminal OUT is set to the high level. Consequently, the first stage shift register unit circuit 121₁ outputs a high-level output signal OUT1. Output signals OUT2, OUT3, . . . , OUTn of the second and subsequent stage shift register unit circuits 121₂, 121₃, . . . , 121ₙ are also set to the high level in the same manner as the output signal OUT1 of the first stage shift register unit circuit 121₁. Consequently, all-on operation in the case of setting the gate start pulse signal GST to the high level is performed.

As a result, the same as the above-described respective embodiments, when the thin film transistor T7 having the gate connected to the all-on control terminal AON supplied with the gate all-on control signal GAON set to the high level is turned on, the power supply voltage VDD is supplied to the output terminal OUT via the thin film transistor T7 and the output terminal OUT is set to the high level. Consequently, the first stage shift register unit circuit 121₁ outputs the high-level output signal OUT1. Output signals OUT2, OUT3, . . . , OUTn of the second and subsequent stage shift register unit circuits 121₂, 121₃, . . . , 121ₙ, are also set to the high level in the same manner as the output signal OUT1 of the first stage shift register unit circuit 121₁. Consequently, all-on operation in the case of setting the gate start pulse signal GST to the high level is performed.

In the above-described manner, the shift register 121 formed of the shift register unit circuits 1217 according to the present embodiment outputs the high-level output signals OUT1, OUT2, . . . , OUTn as gate signals G1, G2, . . . , Gn, and the all-on operation is performed.

Therefore, according to the seventh embodiment, the shift register can be made to perform the all-on operation regardless of the signal level of the gate start pulse signal GST received in the set terminal SET.

### Eighth Embodiment

Next, an eighth embodiment of the present invention will be described.

In the present embodiment, only FIG. 1 used in the first embodiment will be referenced.

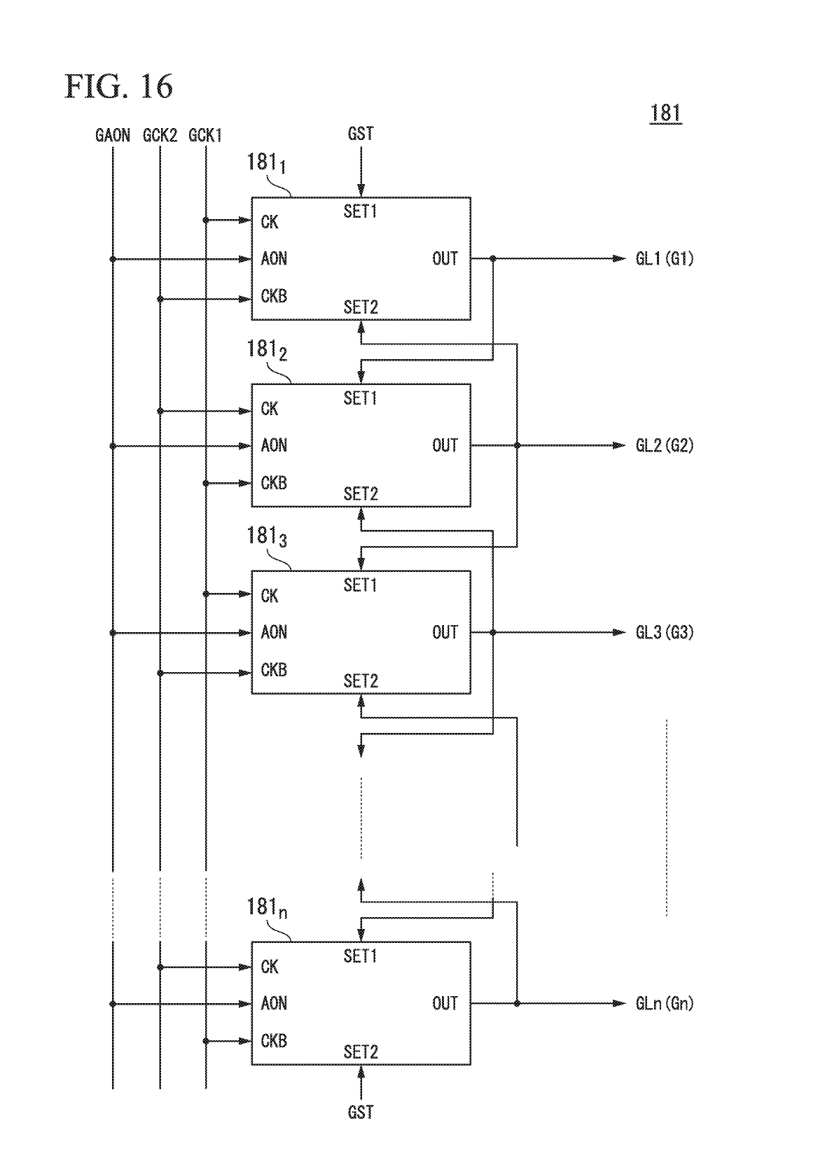

A display device according to the eighth embodiment includes a shift register 181 illustrated in FIG. 16 instead of a shift register 121 illustrated in FIG. 2 referenced in the seventh embodiment described above. Other configurations are the same as the first embodiment.

FIG. 16 is a schematic block diagram illustrating an exemplary configuration of a shift register 181 according to the eighth embodiment. As illustrated in FIG. 2, the shift register 181 includes a plurality of shift register unit circuits 181₁, 181₂, 181₃, . . . , 181ₙ corresponding to a plurality of scanning lines GL1, GL2, GL3, . . . , GLn. The plurality of shift register unit circuits 181₁, 181₂, 181₃, . . . , 181ₙ is connected in cascade.

Each of the plurality of shift register unit circuits 181₁, 181₂, 181₃, . . . , 181ₙ has the same configuration, and when each of the shift register unit circuits 181₁, 181₂, 181₃, . . . , 181ₙ is indicated hereinafter, the shift register unit circuit will be referred to as a “shift register unit circuit 1811” for convenience. The shift register unit circuit 1811 includes clock terminals CK, CKB, two set terminals SET1, SET2, an output terminal OUT, and an all-on control terminal AON.

In odd-numbered stage shift register unit circuits among the plurality of shift register unit circuits 181₁, 181₂, 181₃, . . . , 181ₙ, the gate clock signal GCK1 is received in the clock terminals CK and the gate clock signal GCK2 is received in the clock terminals CKB. In contrast, in an even-numbered stage shift register unit circuit, the gate clock signal GCK2 is received in the clock terminal CK and the gate clock signal GCK1 is received in the clock terminal CKB. The gate all-on control signal GAON is received in the all-on control terminal AON in each of the plurality of shift register unit circuits 181₁, 181₂, 181₃, . . . , 181ₙ.

Among the plurality of shift register unit circuits 181₁, 181₂, 181₃, . . . , 181ₙ, the gate start pulse signal GST is received in the set terminal SET1 of a first stage shift register unit circuit 181₁, and an output signal of a previous stage shift register unit circuit is received in the set terminal SET1 in each of second and subsequent stage shift register unit circuits (namely, from the second stage shift register unit circuit to the n^{th} stage shift register unit circuit). Furthermore, the gate start pulse signal GST is received in the set terminal SET2 of the final n^{th} stage shift register unit circuit 181ₙ, and an output signal of a subsequent shift register unit circuit is received in the set terminal SET2 in each of n−1^{th} and previous stage shift register unit circuits (namely, from the first stage shift register unit circuit to the n−1^{th} stage shift register unit circuit). For example, the output signal OUT1 of the previous stage shift register unit circuit 181₁ is received in the set terminal SET1 of the shift register unit circuit 181₂, and the output signal OUT3 of the subsequent stage shift register unit circuit 181₃ is received in the set terminal SET2 of the shift register unit circuit 181₂.

Meanwhile, in each of the plurality of shift register unit circuits 181₁, 181₂, 181₃, . . . , 181ₙ, scanning switch signals UD, UDB to switch a scanning direction (shift direction) are received although not illustrated.

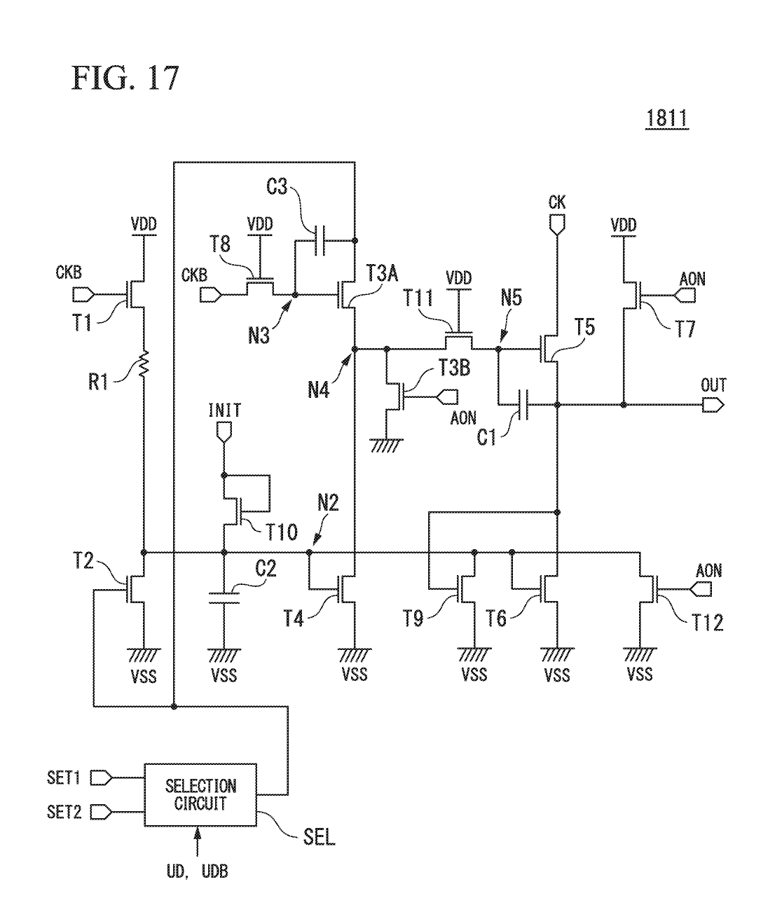

FIG. 17 is a circuit diagram illustrating an exemplary configuration of the shift register unit circuit 1811 according to the eighth embodiment. The shift register unit circuit 1811 includes a selection circuit SEL in a configuration of a shift register unit circuit 1217 according to the seventh embodiment illustrated in FIG. 15. Other configurations are the same as the shift register unit circuit 1217 according to the seventh embodiment. Based on the scanning switch signals UD, UDB, the selection circuit SEL selects and fetches, as an input signal, any one of the output signal (or gate start pulse signal GST) of the previous stage shift register unit circuit received in the set terminal SET1 and the output signal (or gate start pulse signal GST) of the subsequent stage shift register unit circuit received in the set terminal SET2.

For example, the selection circuit SEL provided at the second stage shift register unit circuit 181₂ selects any one of the output signal OUT1 of the first stage shift register unit circuit 1811 and the output signal OUT3 of the third stage shift register unit circuit 181₃. The selection circuit SEL supplies the selected output signal to a gate of a thin film transistor T2 and further supplies the same to a drain of a thin film transistor T3A connected to the set terminal SET in the above-described seventh embodiment.

In the present embodiment, the selection circuit SEL functions as a scanning switch circuit to switch a scanning direction based on the scanning switch signals UD, UDB. Here, the scanning direction is outputting order of the output signals OUT1, OUT2, OUT3, . . . , OUTn of the plurality of shift register unit circuits 181₁, 181₂, 181₃, . . . , 181ₙ illustrated in FIG. 16, and scanning in the case of outputting the output signals OUT1, OUT2, OUT3, . . . , OUTn in an ascending order from the first stage shift register unit circuit 181₁ to the final n^{th} stage shift register unit circuit 181, will be referred to as forward scanning. On the other hand, scanning in the case of outputting the output signals OUT1, OUT2, OUT3, . . . , OUTn in a descending direction from the final n^{th} stage shift register unit circuit 181ₙ to the first stage shift register unit circuit 1811 will be referred to as backward scanning.

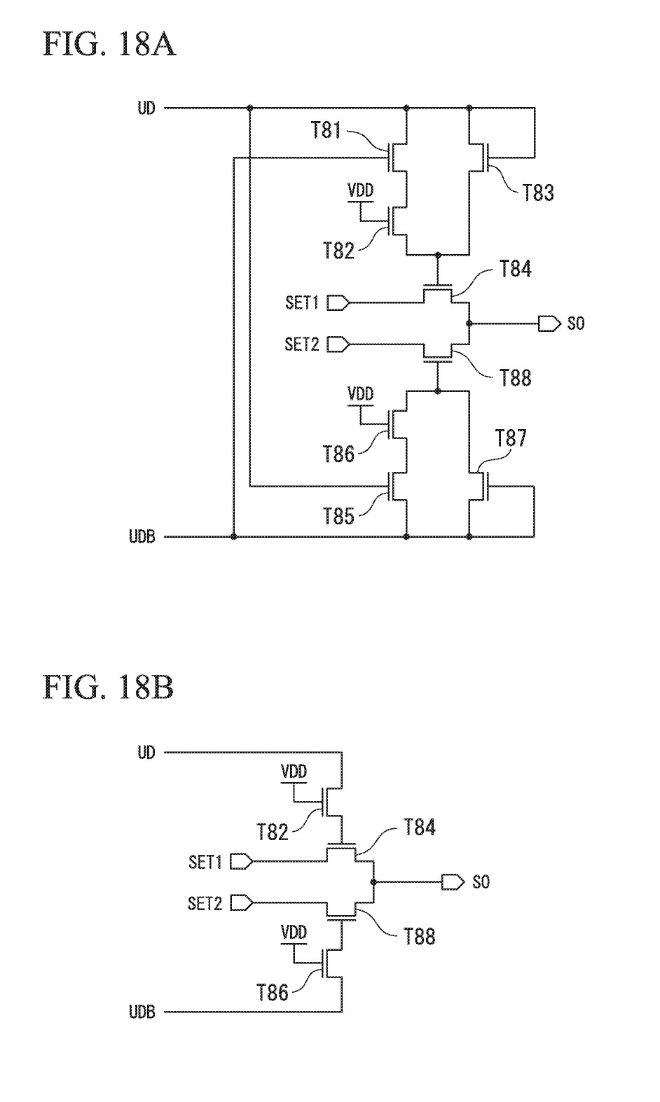

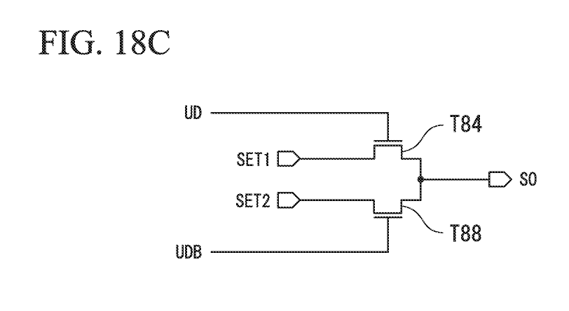

FIGS. 18A to 18C are circuit diagrams illustrating detailed examples of the shift register unit circuit according to the eighth embodiment, and illustrate exemplary configurations of the selection circuit SEL. The selection circuit (scanning switch circuit) illustrated in FIG. 18A includes thin film transistors T81, T82, T83, T84, T85, T86, T87, T88. Here, the thin film transistor T81 has a drain supplied with the scanning switch signal UD and a gate supplied with the scanning switch signal UDB that is an inverted signal of the scanning switch signal UD. The thin film transistor T81 has a source connected to a drain of the thin film transistor T82, and the thin film transistor T82 has a gate supplied with the power supply voltage VDD. The thin film transistor T83 has a drain supplied with the scanning switch signal UD, a gate connected to the drain, and a source connected to a gate of the thin film transistor T84 together with a source of the above-described thin film transistor T82. In other words, the thin film transistor T83 is diode-connected, in which a node corresponding to an anode is supplied with the scanning switch signal UD and a node corresponding to a cathode is connected to the gate of the thin film transistor T84. The thin film transistor T84 has one end of a current path connected to the set terminal SET1 and the other end of the current path connected to an output terminal SO.

Furthermore, the thin film transistor T85 has a source supplied with the scanning switch signal UDB and a gate supplied with the scanning switch signal UD. The thin film transistor T85 has a drain connected to a source of the thin film transistor T86, and the thin film transistor T86 has a gate supplied with the power supply voltage VDD. The thin film transistor T87 has a source supplied with the scanning switch signal UDB, a gate connected to the source, and a drain connected to a gate of the thin film transistor T88 together with a drain of the above-described thin film transistor T86. In other words, the thin film transistor T87 is diode-connected, in which a node corresponding to an anode is supplied with the scanning switch signal UDB and a node corresponding to a cathode is connected to the gate of the thin film transistor T88.

The thin film transistor T88 has one end of a current path connected to the set terminal SET2 and the other end of the current path connected to an output terminal SO.

The selection circuit illustrated in FIG. 18B omits the thin film transistors T81, T83, T85, T87 in the above-described configuration illustrated in FIG. 18A, and is made to have a configuration such that the scanning switch signal UD is supplied to the drain of the thin film transistor T82 and the scanning switch signal UDB is supplied to the source of the thin film transistor T86.

The selection circuit illustrated in FIG. 18C omits the thin film transistors T81, T82, T83, T85, T86, T87 in the above-described configuration illustrated in FIG. 18A, and is made to have a configuration such that the scanning switch signal UD is supplied to the gate of the thin film transistor T84 and the scanning switch signal UDB is supplied to the gate of the thin film transistor T88.

Next, operation according to the present embodiment will be described.

First, basic operation of the selection circuit SEL will be described, and then operation of the shift register unit circuit 181 including the selection circuit SEL and illustrated in FIG. 16 will be described.

### <Operation of Selection Circuit SEL>

First, operation of the selection circuit illustrated in FIG. 18A will be described.

In the case of performing forward scanning, the scanning switch signal UD is set to the high level and the scanning switch signal UDB that is the inverted signal thereof is set to the low level. In this case, the thin film transistor T81 supplied with the low-level scanning switch signal UDB becomes an OFF-state. The thin film transistor T83 has a drain supplied with the high-level scanning switch signal UD. The gate of the thin film transistor T84 is charged via the thin film transistor T83 to voltage (VDD−Vth) decreased by threshold voltage Vth of the thin film transistor T83 from the power supply voltage VDD corresponding to the high level of the scanning switch signal UD. Therefore, the thin film transistor T84 is turned on.

On the other hand, the thin film transistor T85 having the gate supplied with the high-level scanning switch signal UD becomes the ON-state. Furthermore, the thin film transistor T86 having the gate supplied with the power supply voltage VDD is also in the ON-state. Therefore, the gate of the thin film transistor T88 is discharged via the thin film transistor T85 and the thin film transistor T86, and the low level is applied to the gate of the thin film transistor T88. Therefore, the thin film transistor T88 is turned off. In this case, the thin film transistor T87 becomes the OFF-state because the source and the gate thereof are supplied with the low-level scanning switch signal UDB.

When the thin film transistor T84 becomes the ON-state and the thin film transistor T88 becomes the OFF-state as described above, the set terminal SET1 is electrically connected to the output terminal SO and the set terminal SET2 is electrically disconnected from the output terminal SO. Due to this, a signal received in the set terminal SET1 is selected and output from the output terminal SO. At this point, gate voltage at the thin film transistor T84 is pushed up by the signal level of the signal received in the set terminal SET1 due to a bootstrap effect by a capacitance component provided between the gate and a channel of the thin film transistor T84. Therefore, the signal received in the set terminal SET1 is transmitted to the output terminal SO without voltage drop caused by the threshold voltage Vth of the thin film transistor T84.

In this case, the output signal from the previous stage shift register unit circuit is received in the set terminal SET1. Therefore, the plurality of shift register unit circuits 181₁, 181₂, 181₃, . . . , 181ₙ illustrated in FIG. 16 outputs the output signals OUT1, OUT2, OUT3, . . . , OUTn in ascending order in the same manner as the above-described respective embodiments, and forward scanning is performed.

Next, in the case of performing backward scanning, the scanning switch signal UD is set to the low level and the scanning switch signal UDB is set to the high level. In this case, the thin film transistor T81 having the gate supplied with the high-level scanning switch signal UDB becomes the ON-state. Furthermore, the thin film transistor T82 having the gate supplied with the power supply voltage VDD is also turned on. Therefore, the gate of the thin film transistor T84 is discharged via the thin film transistor T81 and the thin film transistor T82, and the low level is applied to the gate of the thin film transistor T84. Therefore, the thin film transistor T84 is turned off. In this case, the thin film transistor T83 becomes the OFF-state because the source and the gate thereof are supplied with the low-level scanning switch signal UDB.

On the other hand, the thin film transistor T85 having the gate supplied with the low-level scanning switch signal UD becomes the OFF-state. The thin film transistor T87 has the drain supplied with the high-level scanning switch signal UDB. The gate of the thin film transistor T88 is charged via the thin film transistor T87 to voltage (VDD −Vth) decreased by threshold voltage Vth of the thin film transistor T87 from the power supply voltage VDD corresponding to the high level of the scanning switch signal UDB. Therefore, the thin film transistor T88 is turned on.

When the thin film transistor T84 becomes the OFF-state and the thin film transistor T88 becomes the ON-state as described above, the set terminal SET2 is electrically connected to the output terminal SO and the set terminal SET1 is electrically disconnected from the output terminal SO. Therefore, a signal received in the set terminal SET2 is selected and output from the output terminal SO. At this point, gate voltage at the thin film transistor T88 is pushed up by the signal level received in the set terminal SET2 due to the bootstrap effect by a capacitance component provided between the gate and a channel of the thin film transistor T88. Due to this, the signal received in the set terminal SET2 is transmitted to the output terminal SO without voltage drop caused by the threshold voltage Vth of the thin film transistor T88.

In this case, the output signal from the subsequent stage shift register unit circuit is received in the set terminal SET2. Therefore, the plurality of shift register unit circuits 181₁, 181₂, 181₃, . . . , 181ₙ illustrated in FIG. 16 outputs the output signals OUT1, OUT2, OUT3, . . . , OUTn in descending order opposite to the above-described respective embodiments, and backward scanning is performed.

As described above, according to the configuration of the selection circuit illustrated in FIG. 18A, the signal can be transmitted to the output terminal SO from the set terminal SET1 or the set terminal SET2 without voltage drop caused by the threshold voltage Vth of the thin film transistors T84, T88. Therefore, the scanning direction can be switched while securing an operation margin of the shift register unit circuits.

Furthermore, according to the configuration of the selection circuit illustrated in FIG. 18A, when the gate voltage at the thin film transistors T84, T88 is boosted by the bootstrap effect, the thin film transistors T82, T86 become the OFF-state. Therefore, high voltage generated by the above-described bootstrap effect is not applied to the sources of the thin film transistors T81, T85 each having the gate applied with the low level. Therefore, deterioration of the respective thin film transistors can be suppressed.

Next, operation of the selection circuit illustrated in FIG. 18B will be described.

Next, in the case of performing forward scanning, the scanning switch signal UD is set to the high level and the scanning switch signal UDB is set to the low level. In this case, the high-level scanning switch signal UD is transmitted to the gate of thin film transistor T84 via the thin film transistor T82. At this point, the gate of the thin film transistor T84 is charged to voltage (VDD−Vth) deceased by threshold voltage Vth of the thin film transistor T82 from the power supply voltage VDD corresponding to the high level of the scanning switch signal UD. Consequently, the thin film transistor T84 is turned on. On the other hand, the low-level scanning switch signal UDB is transmitted to the gate of thin film transistor T88 via the thin film transistor T86. At this point, the gate of the thin film transistor T84 is discharged to ground voltage VSS corresponding to the low level of the scanning switch signal UD. Consequently, the thin film transistor T88 is turned off.

Therefore, since the set terminal SET1 is electrically connected to the output terminal SO in the same manner as the above-described selection circuit illustrated in FIG. 18A, the signal received in the set terminal SET1 is selected and output from the output terminal SO. Furthermore, due to the bootstrap effect by a capacitance component provided between the gate and the channel of the thin film transistor T84, the signal received in the set terminal SET1 is transmitted to the output terminal SO without voltage drop caused by the threshold voltage Vth of the thin film transistor T84.

In the case of performing backward scanning also, the description will be given in the same manner as the case of forward scanning. However, in this case, the thin film transistor T88 becomes the ON-state and a signal received in the set terminal SET2 is selected and output from the output terminal SO.

Next, operation of the selection circuit illustrated in FIG. 18C will be described.

Next, in the case of performing forward scanning, the scanning switch signal UD is set to the high level and the scanning switch signal UDB is set to the low level. In this case, the high-level scanning switch signal UD is transmitted to the gate of the thin film transistor T84. Consequently, the thin film transistor T84 is turned on. On the other hand, the low-level scanning switch signal UDB is transmitted to the gate of the thin film transistor T88. Consequently, the thin film transistor T88 is turned off.

Therefore, since the set terminal SET1 is electrically connected to the output terminal SO in the same manner as the above-described respective selection circuits illustrated in FIGS. 18A and 18B, the signal received in the set terminal SET1 is selected and output from the output terminal SO. However, according to the selection circuit in FIG. 18C, it is not possible to obtain the bootstrap effect by the capacitance component provided between the gate and the channel of the thin film transistor T84. Therefore, the signal level of the signal received in the set terminal SET1 is decreased by the threshold voltage Vth of the thin film transistor T84 and then transmitted to the output terminal SO.

In the case of performing backward scanning also, the description will be given in the same manner as the case of forward scanning. However, in this case, the thin film transistor T88 becomes the ON-state and a signal received in the set terminal SET2 is selected and output from the output terminal SO.

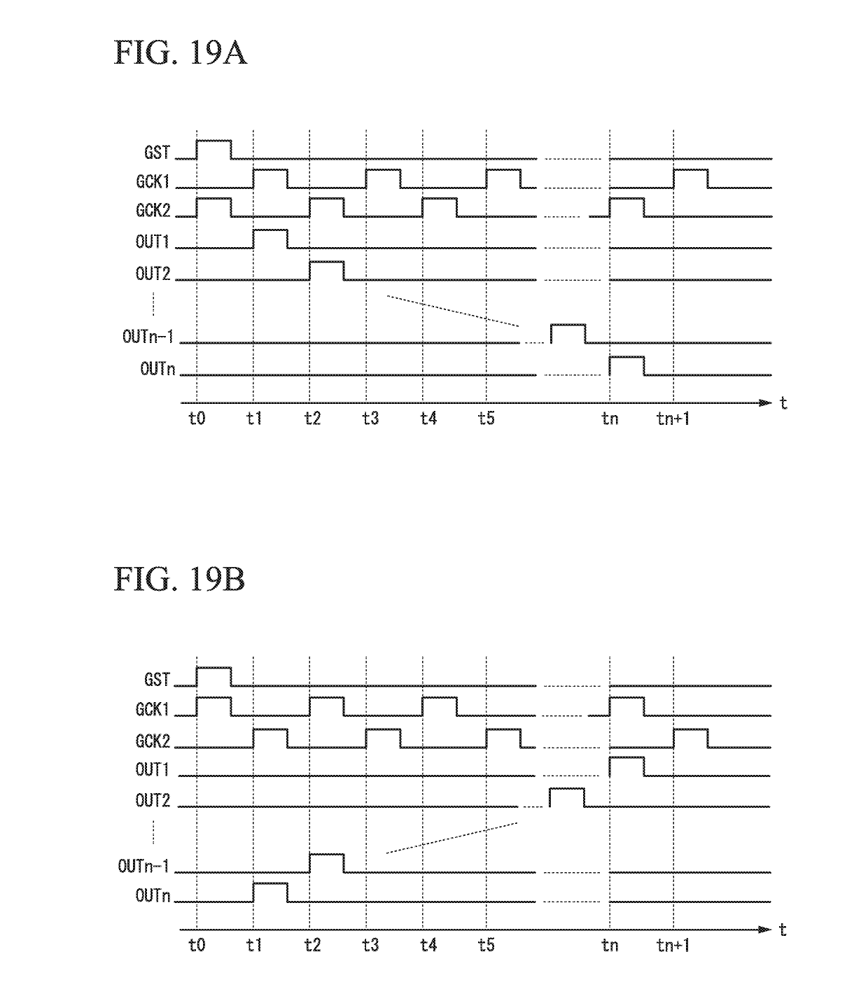

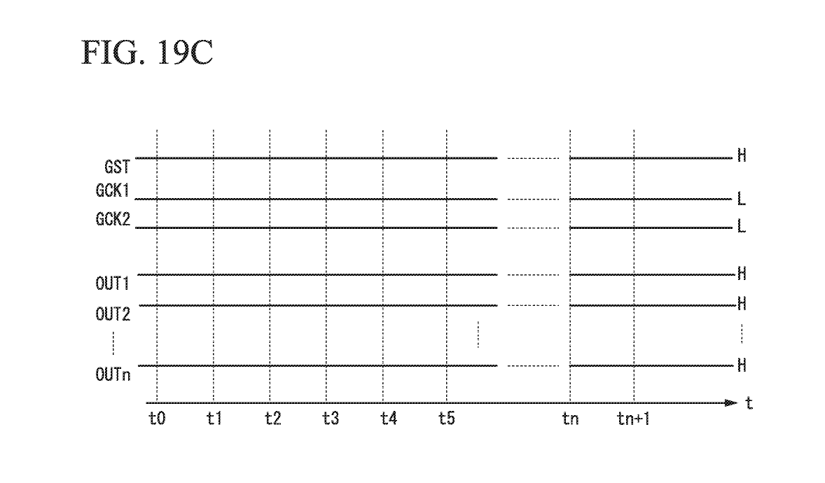

Next, operation of the shift register unit circuit 1811 including the above-described selection circuit SEL will be described with reference to FIGS. 19A to 19C.

FIGS. 19A to 19C are time charts illustrating exemplary operation of the shift register according to the eighth embodiment. FIG. 19A is a time chart during forward scanning, and FIG. 19B is a time chart during backward scanning. In FIGS. 19A to 19C, the high level and the low level of the gate start pulse signal GST and the gate clock signals GCK1, GCK2 are the signal levels corresponding to the operation power supply voltage VDD supplied to the shift register and the ground voltage VSS respectively. Furthermore, in normal operation, the gate all-on control signal GAON is set to the low level. Furthermore, in FIGS. 19A to 19C, OUT1, OUT2, OUTn−1, OUTn represent output signals of the first stage, second stage, n−1^{th} stage, n^{th} stage shift register unit circuits 1811 respectively.

Note that “H” in the drawings represents the high level and “L” represents the low level.

### <Operation in Forward Scanning>

In the case of performing forward scanning, the scanning switch signal UD is set to the high level and the scanning switch signal UDB that is the inverted signal thereof is set to the low level. In this case, as described above, the signal received in the set terminal SET1 is selected by the selection circuit SEL. Therefore, the gate start pulse signal GST received in the set terminal SET1 is fetched into the first stage shift register unit circuit 181₁, and the output signal of the previous stage shift register unit circuit is fetched into the set terminal SET1 in each of the second and subsequent stage shift register unit circuits 181₂, 181₃, . . . , 181ₙ. Therefore, in this case, the output signals OUT1, OUT2, OUT3, . . . , OUTn of the shift register unit circuits 181₁, 181₂, 181₃, . . . , 181ₙ, are output in ascending order in synchronization with the gate clock signals GCK1, GCK2 as illustrated in FIG. 19A in the same manner as the above-described respective embodiments.

### <Operation in Backward Scanning>

In the case of performing backward scanning, the scanning switch signal UD is set to the low level and the scanning switch signal UDB that is the inverted signal thereof is set to the high level. In this case, as described above, the signal received in the set terminal SET2 is selected by the selection circuit SEL. Therefore, the gate start pulse signal GST received in the set terminal SET2 is fetched into the final n^{th} stage shift register unit circuit 1811, and the output signal of the subsequent stage shift register unit circuit is fetched into the set terminal SET2 in each of the first to n−1^{th} stage shift register unit circuits 181₁, 181₂, . . . , 181ₙ₋₁. In this case, the shift register unit circuits 181₁, 181₂, 181₃, . . . , 181ₙ respectively perform operation corresponding to the shift register unit circuits 181ₙ, 181ₙ₋₁, . . . , 181₂, 181₁ in the above-described forward scanning. Therefore, in this case, output signals OUT1, OUT2, OUT3, . . . , OUTn of the shift register unit circuits 181₁, 181₂, 181₃, . . . , 181ₙ are output in descending order opposite to forward scanning in synchronization with the gate clock signals GK1, GK2 as illustrated in FIG. 19B.

### <All-On Operation>

All-on operation is performed in the same manner as the above-described the seventh embodiment. In other words, in this case, when the gate all-on control signal GAON becomes the high level, all of the output signals OUT1, OUT2, OUT3, . . . , OUTn are set to the high level as illustrated in FIG. 19C regardless of the signal level of the gate start pulse signal GST received in the set terminals SET1, SET2, namely, regardless of a selection state of the selection circuit SEL. Consequently, the shift register performs the all-on operation.

As described above, according to the eighth embodiment, the scanning direction can be switched while securing the operation margin.

### Ninth Embodiment

Next, a ninth embodiment of the present invention will be described.

In the present embodiment, FIGS. 1 and 2 used in the first embodiment will also be referenced.

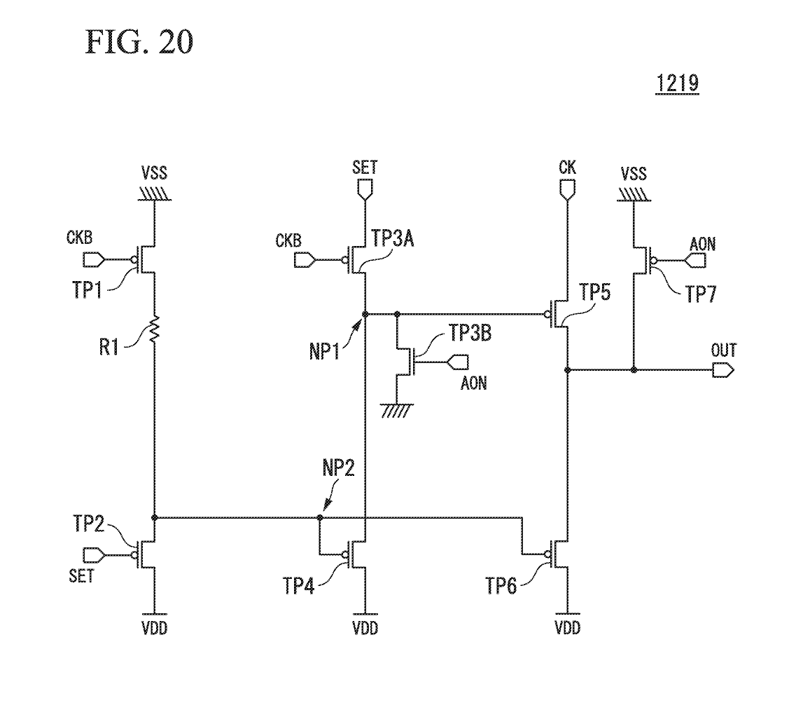

A display device according to the ninth embodiment includes a shift register unit circuit 1219 illustrated in FIG. 20 instead of shift register unit circuits 121₁, 121₂, 121₃, . . . , 121ₙ (namely, shift register unit circuit 1211 illustrated in FIG. 3) constituting the shift register 121 illustrated in FIG. 2 in the above-described the first embodiment. Other configurations are the same as the first embodiment.

FIG. 20 is a circuit diagram illustrating an exemplary configuration of the shift register unit circuit 1219 according to the ninth embodiment. The shift register unit circuits 1219 is configured by replacing thin film transistors T1, T2, T3A, T3B, T4, T5, T6, T7 that are n channel field-effect transistors, in a configuration of the shift register unit circuit 1211 according to the above-described the first embodiment illustrated in FIG. 3, with thin film transistors TP1, TP2, TP3A, TP3B, TP4, TP5, TP6, TP7 that are p channel field-effect transistors, and switching locations of power supply voltage VDD and ground voltage VSS. In the present embodiment, a node NP1 is formed at a connection point between a source of the thin film transistor TP3A and a drain of the thin film transistor TP4, and a node NP2 is formed at a connection point between resistance R1 and a drain of the thin film transistor TP2. Furthermore, in the present embodiment, a signal received in each of a set terminal SET, clock terminals CK, CKB, and an all-on control terminal AON is an inverted signal of the signal received in each of the mentioned terminals in the above-described the first embodiment.

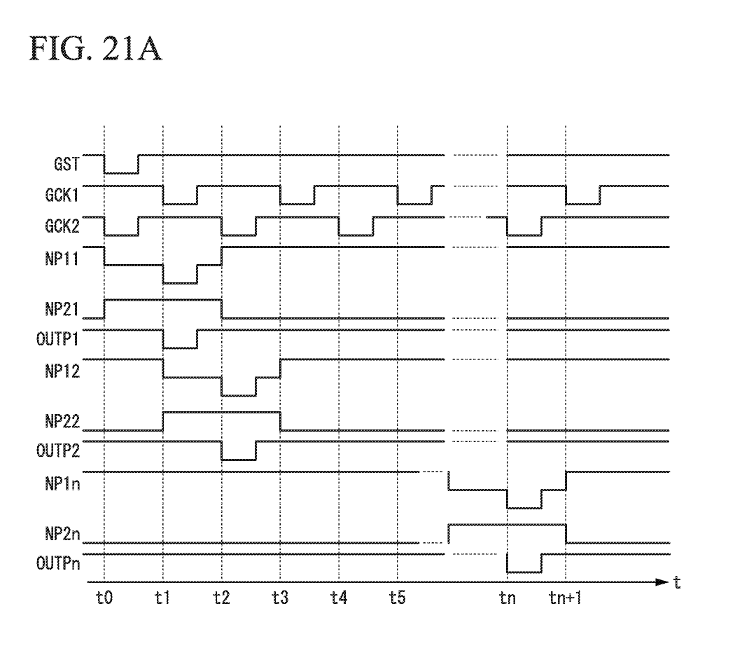

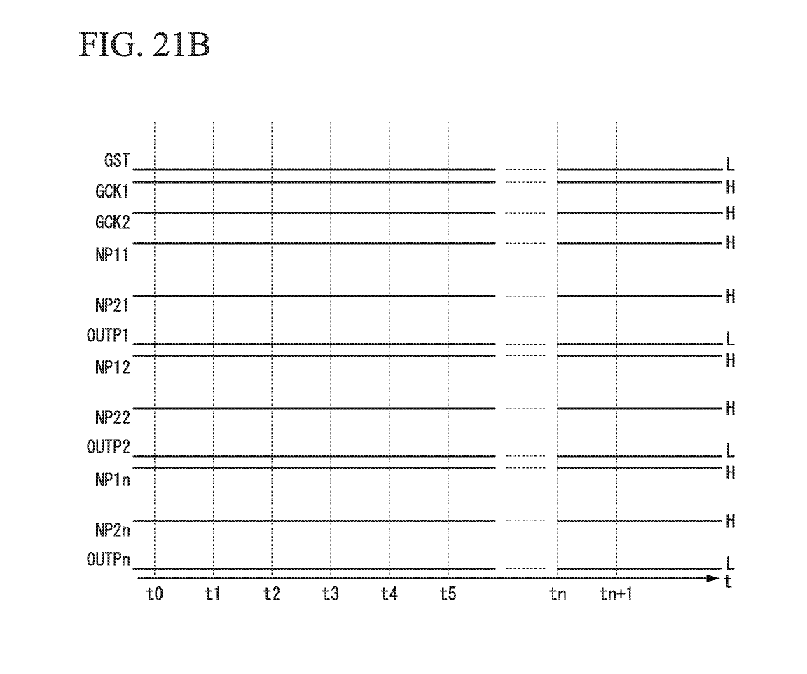

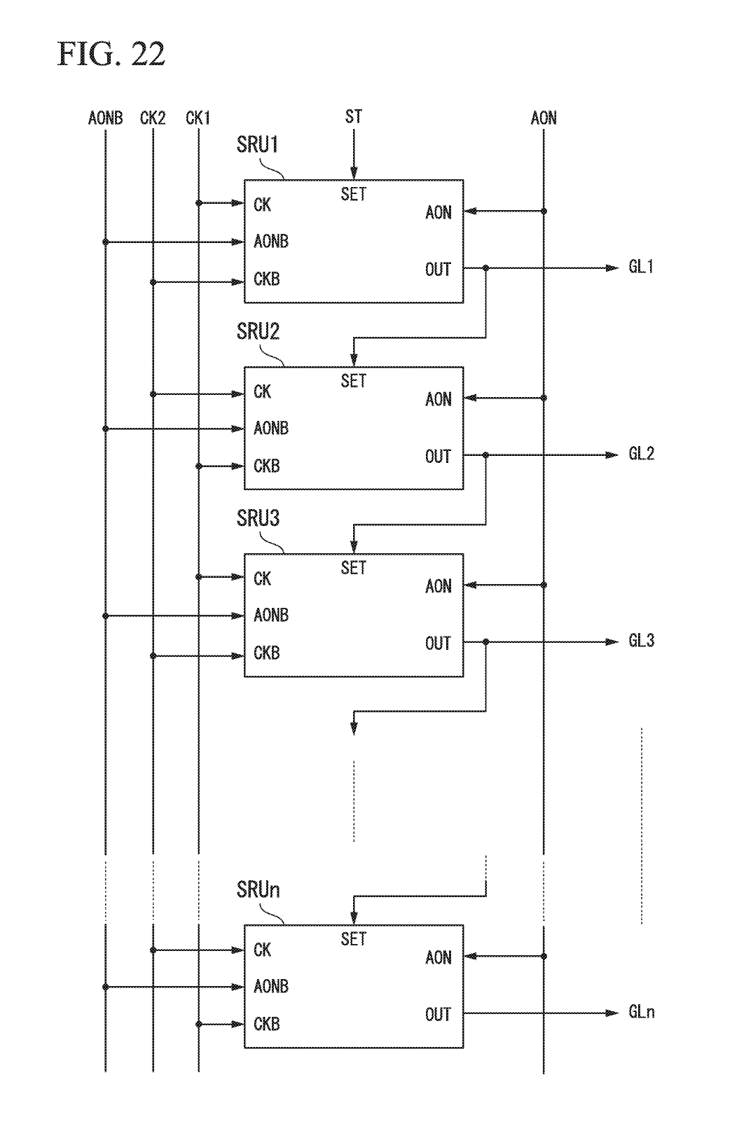

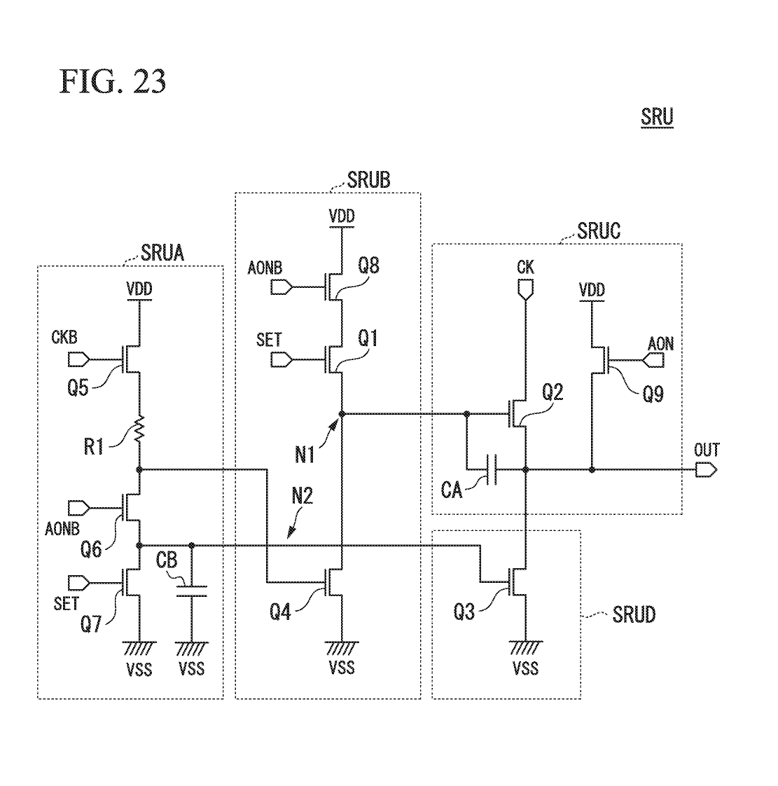

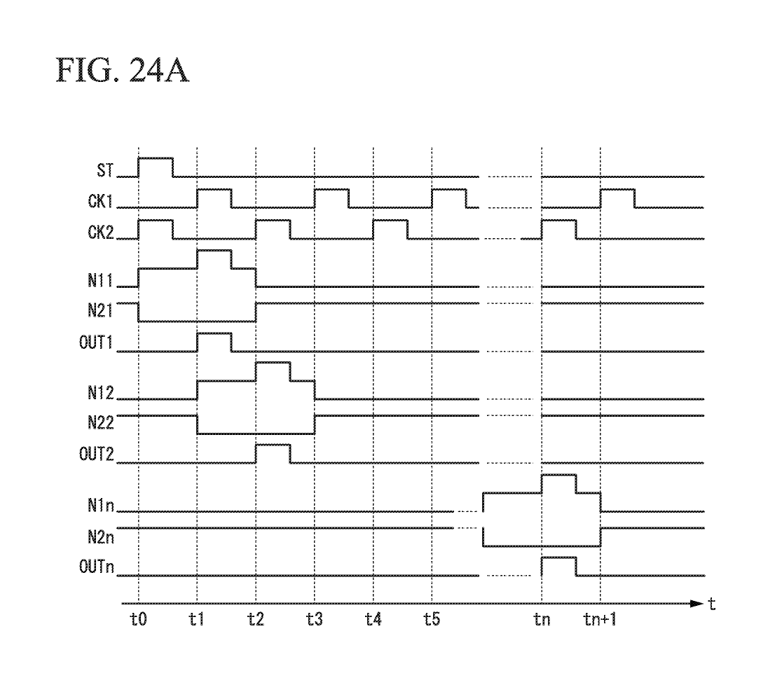

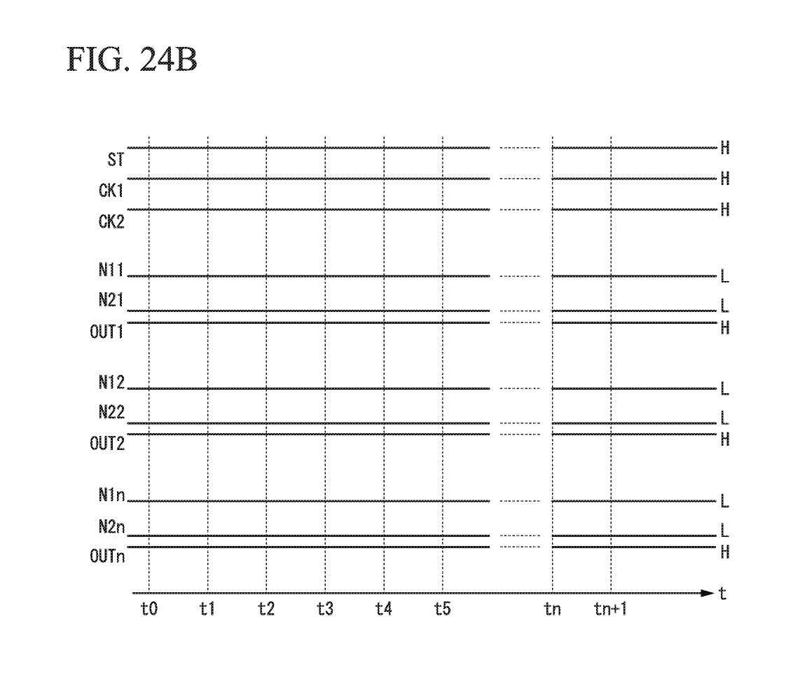

FIGS. 21A and 21B are time charts illustrating exemplary operation of the shift register according to the ninth embodiment. FIG. 21A is a time chart during normal operation and FIG. 21B is a time chart during all-on operation. In FIGS. 21A and 21B, a high level and a low level of a gate start pulse signal GST and gate clock signals GCK1, GCK2 are respectively the signal levels corresponding to the operation power supply voltage VDD supplied to the shift register and the ground voltage VSS. Furthermore, in the case of the present embodiment, the gate all-on control signal GAON is set to the high level in normal operation. In contrast, the gate all-on control signal GAON is set to the low level in the all-on operation. Furthermore, in FIGS. 21A and 21B, NP11 and NP21 represent the nodes NP1 and NP2 of the first stage shift register unit circuit 1211, NP12 and NP22 represent the nodes NP1 and NP2 of the second stage shift register unit circuit 121₂, NP1n and NP2n represent the nodes NP1 and NP2 of the n^{th} stage shift register unit circuit 121ₙ, and OUTP1, OUTP2, OUTPn represent output signals of the first, second, and n^{th} stage shift register unit circuits 1219 respectively.

Note that “H” in the drawings represents the high level and “L” represents the low level.

Basically, operation of the shift register unit circuit 1219 is described in the same manner as the first embodiment by inverting respective signal levels in operation of the shift register unit circuit 1211 according to the above-described the first embodiment. However, in the present embodiment, the respective output signals OUTP1, OUTP2, OUTP3, . . . , OUTPn of the plurality of shift register unit circuits 121₁, 121₂, 121₃, . . . , 121ₙ become low-level pulse signals in normal operation and are maintained at the low level in the all-on operation as illustrated in FIG. 21A.

Here, in the case of using the p channel field-effect transistor as a thin film transistor for a pixel TC in a pixel portion PIX, the thin film transistor for a pixel TC in all of the pixel portions PIX can be made conductive when the respective output signals OUTP1, OUTP2, OUTP3, . . . , OUTPn of the plurality of shift register unit circuits 121₁, 121₂, 121₃, . . . , 121ₙ, are made to become the low level in the all-on operation.

Furthermore, the same as the first embodiment, in the case of using the n channel field-effect transistor as the thin film transistor for a pixel TC in the pixel portion PIX, gate signals G1, G2, . . . , Gn on scanning lines GL1, GL2, . . . , GLn need to be set to the high level in order to make the thin film transistors for a pixel TC in all of the pixel portions PIX conductive in the all-on operation. Therefore, in this case, it is only to provide, for example, an inverter circuit to invert the signal levels of the output signals OUTP1, OUTP2, OUTP3, . . . , OUTPn of the shift register unit circuit 1219.

According to the present embodiment, since the p channel field-effect transistor is used as the thin film transistor constituting the shift register unit circuit 1219, the shift register capable of performing the normal operation and all-on operation without increasing the number of transistors can be configured in the case of using the p channel field-effect transistor as, for example, the thin film transistor for a pixel TC in the pixel portion PIX.

Furthermore, in the present embodiment, the shift register unit circuit 1219 is configured by replacing each of thin film transistors in the shift register unit circuit 1211 in the above-described the first embodiment with the p channel field-effect transistor. However, as for respective shift register unit circuits according to second to eighth embodiments, each of the thin film transistors can also be replaced with the p channel field-effect transistor in the same manner.

While embodiments of the present invention have been described above, the characterizing portions unique to the respective embodiments of the above-described first to ninth embodiments can be arbitrarily combined, and the same is applied to the above-described modified examples.

Furthermore, the present invention is not limited to the above-described embodiments, and various modifications, changes, and replacements can be made within a scope not departing from the gist of the present invention.

For example, according to the above-described embodiments, each one of the thin film transistors may have a common gate and may be provided as a plurality of thin film transistors having current paths (source/drain) connected in series or in parallel.

### INDUSTRIAL APPLICABILITY

An embodiment of the present invention is applicable to a shift register, a display device, and the like in which the number of transistors can be reduced.

### DESCRIPTION OF REFERENCE NUMERALS

100 Display device
110 Display unit
120 Scanning line drive circuit (Gate driver)
121 Shift Register
121₁ to 121ₙ, 1211 Shift register unit circuit
130 Signal line drive circuit (Source driver)
131 Shift Register
140 Display control circuit
150 Power supply circuit
120 Scanning line drive circuit
121 Shift register
130 Signal line drive circuit
131 Shift Register
140 Display control circuit
181₁ to 181ₙ Shift register unit circuit
1211 Shift register unit circuit
1211A Setting unit
1211B First output controller
1211C Second output controller
C1, C2, C3 Capacitor
CS Pixel capacitance portion
GL1 to GLn Scanning line
PIX Pixel portion
R1 Resistance
SEL Selection circuit
SL1 to SLm Signal line
T1, T2, T3A, T3B, T4 to T12, T81 to T88 Thin film transistor
Tcom Counter electrode
TP1 to TP7 Thin film transistor
TS1 to TSm Thin film transistor for signal line selection

1: A shift register comprising a plurality of unit circuits connected in cascade, each of the unit circuits comprising:
a first output transistor having a current path connected between an output terminal and a clock terminal, the clock terminal being configured to be supplied with a first clock signal;
a second output transistor having a current path connected between the output terminal and a predetermined potential node;
a setting unit configured to set a signal level of the output terminal to a predetermined signal level in a case where a control signal is active, the control signal being adapted to set the levels of output signals of the plurality of unit circuits to the predetermined signal level;
a first output controller configured to
turn off the first output transistor in response to the control signal in the case where the control signal is active,
turn on the first output transistor by supplying a control electrode of the first output transistor with an input signal in response to one of a second clock signal succeeding the first clock signal and a signal synchronized with the first clock signal in a case where the control signal is inactive; and
a second output controller configured to
turn off the second output transistor in the case where the control signal is active, and
turn off the first output transistor and further turn on the second output transistor in response to one of a second clock signal succeeding the first clock signal and a signal synchronized with the first clock signal in the case where the control signal is inactive.

2: The shift register according to claim 1, wherein the first output controller comprises:
a first field-effect transistor having a current path connected between an input terminal configured to be supplied with the input signal and a control electrode of the first output transistor, the first field-effect transistor comprising a gate connected to a clock terminal, the clock terminal being configured to be supplied with one of the second clock signal succeeding the first clock signal and the signal synchronized with the first clock signal; and
a second field-effect transistor having a current path connected between a source of the first field-effect transistor and the predetermined potential node, the second field-effect transistor comprising a gate configured to be supplied with the control signal.

3: The shift register according to claim 2, wherein the first output controller further comprises:
a third field-effect transistor having a current path interposed between a clock terminal and the gate of the first field-effect transistor, the clock terminal being configured to be supplied with one of the second clock signal succeeding the first clock signal and the signal synchronized with the first clock signal, the third field-effect transistor comprising a gate supplied with predetermined potential, the first field-effect transistor being included in the first output controller.

4: The shift register according to claim 3, wherein
the first output transistor is a field-effect transistor, and
the first output transistor further comprises:
a first capacitor connected between a drain and a gate of the first output transistor; and
a second capacitor connected between a drain and the gate of the first field-effect transistor.

5: The shift register according to claim 4, wherein
the second output transistor is a field-effect transistor, and
the second output transistor further comprises:
a fourth field-effect transistor comprising a gate connected to a drain of the second output transistor, the fourth field-effect transistor comprising a drain connected to a gate of the second output transistor.

6: The shift register according to claim 5, further comprising:
a fifth field-effect transistor comprising a source connected to the gate of the second output transistor, the fifth field-effect transistor comprising a gate and a drain applied with an initialization signal.

7: The shift register according to claim 6, further comprising:
a sixth field-effect transistor having a current path interposed between the source of the first field-effect transistor and the gate of the first output transistor, the sixth field-effect transistor comprising a gate supplied with predetermined potential.

8: The shift register according to claim 7, further comprising:
a seventh field-effect transistor having a current path connected between the gate of the second output transistor and the predetermined potential node, the seventh field-effect transistor comprising a gate configured to be supplied with the control signal.

9: The shift register according to claim 1, wherein
each of the plurality of unit circuits further comprises:
a selection circuit configured to select and fetch, as the input signal, one of an output signal of a previous stage unit circuit and an output signal of a subsequent stage unit circuit.

10: The shift register according to claim 8, wherein
the first output transistor, the second output transistor, the first field-effect transistor, the third field-effect transistor, the fourth field-effect transistor, the fifth field-effect transistor, the sixth field-effect transistor, the seventh field-effect transistor, and the second field-effect transistor are field-effect transistors of a same conductivity type,
the first output transistor, the second output transistor, the first field-effect transistor, the third field-effect transistor, the fourth field-effect transistor, the fifth field-effect transistor, the sixth field-effect transistor, the seventh field-effect transistor, and the second field-effect transistor are either an n channel field-effect transistor or a p channel field-effect transistor.

11: A display device comprising:
a drive circuit comprising the shift register according to claim 1.
